(19) United States
(12) Patent Application Publication
(10) Pub. No.: US 2026/0089038 A1
(43) Pub. Date: Mar. 26, 2026

(54) BIDIRECTIONAL SHORT PULSE WIDTH MODULATION (PWM) CODE (SPC) COMMUNICATION

(71) Applicant: Infineon Technologies AG, Neubiberg (DE)

(72) Inventor: Dirk Hammerschmidt, Finkenstein (AT)

(21) Appl. No.: 18/895,647

(22) Filed: Sep. 25, 2024

(51) Int. Cl. H04L 25/49; H04L 7/06

(52) U.S. Cl. CPC H04L 25/4902; H04L 7/06

(57) ABSTRACT

The described techniques address issues related to conventional bidirectional SPC protocols by providing various signaling schemes to enable bidirectional SPC communications without interrupting other sensor communications. The bidirectional signaling schemes may provide further advantages such as reducing device current draw compared to conventional bidirectional SPC communication schemes, reducing transmission times, increasing data rates, and reducing sensor complexity.

### TECHNICAL FIELD

The disclosure generally relates to the use of data communications and, more particularly, to the use of bidirectional data communications in accordance with a short pulse width modulation (PWM) code (SPC) protocol.

### BACKGROUND

Sensors are implemented in a variety of applications that require the communication of measured sensor data to another component of an overall system, such as a microcontroller or electronic control unit (ECU) for instance. Such communications may include the SAE J2716 SENT (Single Edge Nibble Transmission) protocol, which is a point-to-point scheme for transmitting signal values from a secondary device (e.g. a sensor) to a primary device (e.g. a microcontroller, ECU, etc.). However, some important features are omitted in the SENT standard, and thus the SPC protocol was developed to address these issues and provide further enhancement. Nonetheless, the current SPC protocol is generally implemented to enable the primary device to listen to data transmissions from the connected secondary devices, and thus conventional SPC protocols often implement unidirectional versus bidirectional communications. Attempts to expand the SPC protocol to include bidirectional communications suffer from various drawbacks, and thus the use of conventional SPC protocols to facilitate bidirectional communications have been inadequate.

### BRIEF DESCRIPTION OF THE DRAWINGS/FIGURES

The accompanying drawings, which are incorporated herein and form a part of the specification, illustrate the aspects of the present disclosure and, together with the description, further serve to explain the principles of the aspects and to enable a person skilled in the pertinent art to make and use the aspects.

FIG. 1 illustrates the time-varying state of a data line for conventional SPC communications;

FIG. 2 illustrates a time-varying state of a data line for conventional bidirectional SPC communications;

FIG. 3 illustrates an example communication system implementing bidirectional SPC communications, in accordance with one or more embodiments of the disclosure;

FIG. 4 illustrates additional detail with respect to the example communication system as shown in FIG. 3, in accordance with one or more embodiments of the disclosure;

FIGS. 5-14 illustrate example bidirectional signaling schemes implemented by a device and a corresponding time-varying state of a data line for bidirectional SPC communications, in accordance with one or more embodiments of the disclosure; and

FIGS. 15-19 illustrate example signaling schemes to implement an alternate SPC trigger signal with increased resolution and reference time base delivery, in accordance with one or more embodiments of the disclosure.

The example aspects of the present disclosure will be described with reference to the accompanying drawings. The drawing in which an element first appears is typically indicated by the leftmost digit(s) in the corresponding reference number.

### SUMMARY

As discussed in further detail herein, SPC communication protocols are commonly used to support communications between different devices. For example, the SPC communication protocol may be implemented to facilitate communications between one or more secondary devices (e.g. sensors) and a primary device (e.g. a microcontroller, an ECU, etc.), depending upon the particular application. The SPC communication protocol is a known protocol that includes enhanced interface features based on the Single Edge Nibble Transmission (SENT) protocol. For instance, the SPC protocol may be implemented based on two different architectures: with an open drain or with a push-pull output stage.

Again, the SENT protocol is defined by the Society of Automotive Engineers (SAE) J2716 specification at the time of this writing. However, the SPC communication protocol introduces a Master Trigger Pulse (MTP) into the SENT frame definition, which acts as an address and assigns a unique time-encoded length to each sensor in terms of a multiple of a pre-programmed unit time (UT) value. This allows a single primary device to manage multiple secondary devices using the same wired interface, which can reduce costs compared to the original one-to-one SENT specification. A typical SPC-based communication system may include one or more sensors coupled to a ECU via a communication path. Thus, the SPC protocol may be implemented in accordance with a synchronous mode of operation (e.g. when a single sensor is connected to the ECU), or via a bus mode of operation (e.g. when more than one sensor is connected to the same ECU via a shared communication path).

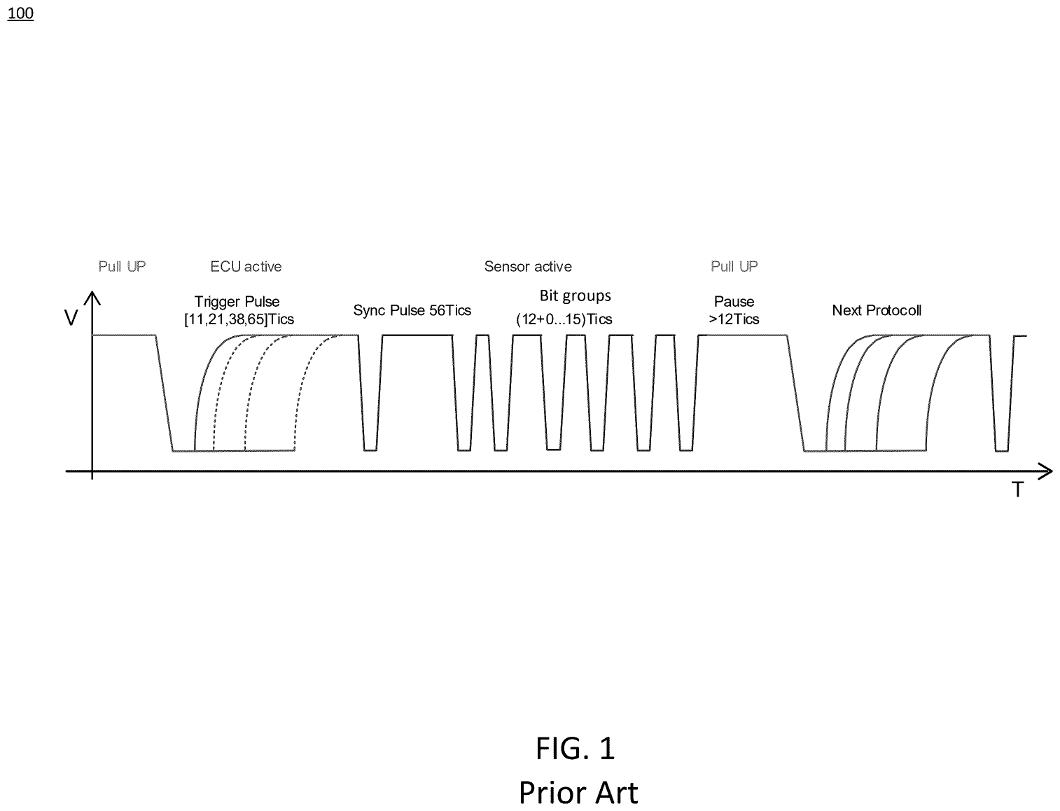

FIG. 1 illustrates the time-varying state of a data line for conventional SPC communications. In this example, a trigger pulse is transmitted by an ECU via a data line, which may form part of a communication link. The ECU may do so, for example, by pulling down or otherwise driving the data line to a reference voltage (e.g. 0V), as shown in FIG. 1, for a specific amount of time based upon the data that is to be encoded, and then releasing the data line or otherwise driving the data line back to the pull up state, which is shown in FIG. 1 as a predetermined voltage level V. In other words, the ECU may generate the trigger pulse in accordance with a PWM scheme in which the length of the trigger pulse encodes a specific value.

That is, the trigger pulse has a duration, which is also referred to herein as a length, expressed in terms of a unit time also referred to as tics. The length of the trigger pulse in is measured by the sensors coupled that receive the trigger pulse transmission. The trigger pulse therefore has a variable duration, which is a function of the intended data to be encoded This encoded data may represent, for example, the address of a recipient sensor from which sensor data is being requested, and is measured by each sensor from the falling edge to the next rising edge, as shown in FIG. 1. That is, the trigger pulse length may be considered a low time on the data wire used for SPC communications, i.e. the time duration during which the ECU pulls the data line to a reference voltage (e.g. ground).

Again, the trigger pulse length may be, for example, expressed as a multiple of a pre-programmed unit time (UT) value, which is quantized using “tics” that are established by the ECU and each sensor as part of a clock synchronization process. This is a known part of the SENT and SPC protocols and is implemented by way of the sensor's sync pulse transmission as shown in FIG. 1, which has a predetermined duration of 56 tics in terms of the sensor's clock frequency. The ECU may then receive this sync pulse transmission and, as it has a known length of 56 tics, then calibrate its own reference clock frequency to match that of the sensor. In other words, the ECU may adjust its clock frequency such that the tic values implemented by the ECU match those of the sensor. The use of the quantized tic time values and calibration/synchronization process allows for lower-cost clocks to be implemented as long as each device is aware of and provides a ±20% clock tolerance.

The trigger pulse length is thus shown in FIG. 1 as being 11, 21, 38, or 65 unit time (UT) values, or “tics,” which are defined in accordance with the conventional SPC protocol. The tic time values are based upon the clock frequency of the relevant device, and typically represent values between 0.25 to 5 microseconds. These different UT values may function to identify the target recipient from which sensor data is being requested, with up to four sensors being supported, i.e. one for each of the different trigger pulse length values as shown. Each sensor may thus determine whether the ECU is requesting sensor data from that particular sensor by comparing the measured time duration of the trigger pulse to a predetermined range of time durations identified for each sensor. Thus, the trigger pulse enables each sensor to discriminate whether the ECU is requesting sensor data from that sensor or another sensor (in which case the trigger pulse may be ignored).

In other words, when used in the bus mode, the trigger pulse may enable the ECU to transmit two bit values as time-encoded data, which again is a function of the length of the trigger pulse. For instance, a trigger pulse having a length of 11 tics may represent 00, whereas trigger pulse lengths of 21, 38, and 65 tics may represent 01, 10, and 11, respectively. These different trigger pulse lengths may be used as bus addresses (as noted above), or to encode configuration data. Thus, the different trigger pulse lengths may be referred to as bus codes. Each sensor's SPC ID register may comprise a 2-bit value that is normally programmed into its EEPROM to enable each sensor to determine whether the measured trigger pulse duration, when decoded, matches this locally-stored ID, indicating that sensor data is being requested from that sensor. In the SPC synchronous mode of operation, the trigger pulse only uses a short (e.g. 11 tics) low time and does not transmit any information.

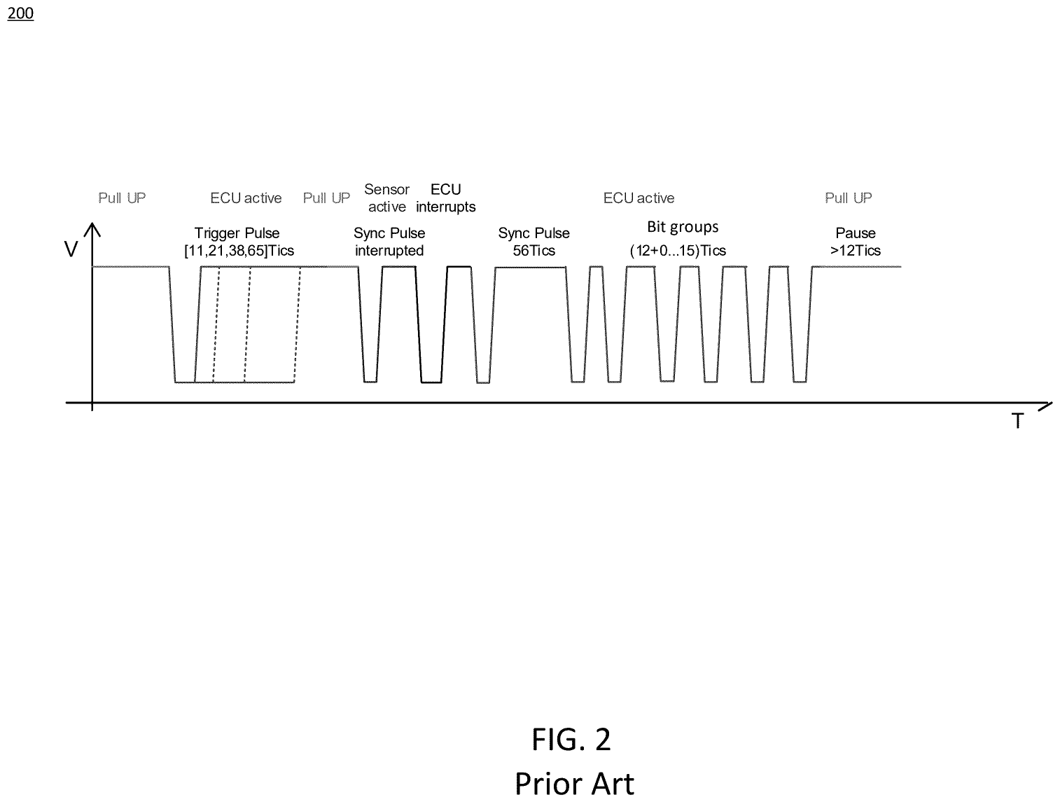

The use of the variable length trigger pulse for the bus mode of operation represents an enhancement from the SENT protocol, as this allows a form of communication from the ECU to the sensors that is not implemented in the purely unidirectional SENT protocol, which in contrast only allows the ECU to receive data from the sensors. Nonetheless, other than the transmission of the trigger pulse by the ECU, the conventional SPC communication protocol is still primarily used for unidirectional communications in which a device receives requested data from the sensors. Attempts have thus been made to expand the SPC communication protocol to include further types of bidirectional communications between the ECU and the sensor(s). To this end, FIG. 2 illustrates a time-varying state of a data line for conventional bidirectional SPC communications.

With continued reference to FIG. 2, the conventional bidirectional SPC communications may be used in the synchronous mode or the bus mode. The conventional bidirectional SPC communications are implemented via an ECU interrupting the transmission of the sync pulse transmission by the sensor, as shown in FIG. 2. This is achieved via the ECU pulling down the data line during the sensor's sync pulse transmission. The sensor may monitor the data line to detect this interruption and, in response, stop its transmission and enter into a receiving mode of operation. For instance, each sensor may determine that the data line has remained low for a period of time exceeding a threshold time period instead of returning to the default high voltage state (e.g. V), and thus enter the receiving mode of operation. However, detecting a low signal during the sensor's sync pulse transmission may result in a high current consumption, because the sensor output driver and the ouput driver of the ECU may work against each other. Thus, it is noted that an increase of the current during the high state of the sync pulse transmission may be used to limit the current consumption and switch the sensor output driver back to a high impedance state once the intterruption has been unambigousliy detected. In any event, after this process has completed, the ECU may then transmit data in accordance with the SPC protocol, which is identical to the protocol that is otherwise used by the sensor to transmit sensor data to the ECU.

For example, the ECU may first transmit the synchronization (sync) pulse instead of the sensor doing so, as well as a series of data bit groups, each including a time-encoded value. The data bit groups may represent four or less bits based upon the particular application. For instance, each of the data bit groups may encode four bits (and in such a case be referred to as data nibbles) or less bits, as is the case for the SENT protocol,. The embodiments as discussed herein may thus implement any suitable number of bits to encode the data bit groups. For instance, the data bit groups may comprise data nibbles of four bits as defined in accordance with the SENT protocol or any other suitable communication protocol. As another example, the data bit groups may comprise a lesser number of bits, such as 3 or less for example, per PWM cycle. In any event, the time between two consecutive falling edges of each transmitted data bit group may define an N-bit value (with N being 4 or less), and thus may represent an encoded number between 0 and 15 when four bits are encoded, between 0 and 7 when 3 bits are encoded, etc. The transmission time (i.e. the time during which the data line remains low) for each data bit group therefore depends on the transmitted encoded data values. All values are multiples of the UT (i.e. tic) value, which again is known by the ECU and the sensors via the use of the synchronization pulse transmission (by the ECU in this scenario).

This scheme allows for the SPC bus mode to remain unchanged as long as no interrupt appears. However, this scheme has drawbacks in that current consumption is required during the interrupt process by way of the ECU pulling down the data line. Additionally, because the sensor may then receive data from the ECU, the sensor also needs to adapt to the ECU timing using the received synchronization pulse to decode the data bit groups, which introduces additional latency and complexity on the sensor side. Furter still, the time associated with the the interrupted response of the sensor consumes unnecessary time.

The embodiments discussed herein address these issues by providing various data line signaling schemes to enable bidirectional SPC communications without interrupting other sensor communications. Section I describes various bidirectional signaling schemes that may provide further advantages such as reducing device current draw compared to conventional bidirectional SPC communication schemes, reducing transmission times, increasing data rates, and reducing sensor complexity, and others as noted further below.

Section II describes a trigger signal that may be implemented to replace the standard trigger pulse used for conventional SPC communications. The trigger signal may encode a time base reference of the primary device as well as state data (e.g. an address, configuration data, commands, etc.), which is transmitted to one or more secondary devices. The transmission of the time base reference enables secondary devices receiving the trigger pulse to then decode the encoded state data. As a result, a higher granularity of state data transmission encoding is achieved to facilitate a larger number of individual states to be represented, with each state being encoded by a smaller number of tic values than that required for the conventional SPC communication protocol, which generally only supports 4 different state encodings (e.g. bus codes) as noted above with respect to FIG. 1. The transmission of the time base reference also allows the secondary devices to adapt their time base to that of the primary device when performing their data transmission, obviating the need to transmit a sync pulse as is required for the conventional SPC communication protocol.

### DETAILED DESCRIPTION

In the following description, numerous specific details are set forth in order to provide a thorough understanding of the aspects of the present disclosure. However, it will be apparent to those skilled in the art that the aspects, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

Again, the embodiments herein are presented in two separate Sections for ease of explanation. Section I is directed to various signaling schemes that may be implemented to utilize bidirectional communications. Section II is directed to the use of an alternative trigger signal that may encode a time base reference of the primary device as well as state data.

Although the embodiments are discussed separately in each Section, it is noted that any of the embodiments described in any of the Sections may be combined with one another, and any of the architectures, processes, types of communications, algorithms, statements, etc., described with respect to the embodiments of any of the Sections are also applicable to the embodiments described in any of the other Sections. For example, any of the embodiments as described herein with respect to the alternative trigger signal of Section II may optionally be implemented as a trigger for the primary and secondary devices to enter into the alternative or the standard modes of communications, as further discussed below.

Additionally, the various embodiments are discussed herein with respect to the use and/or modification of the SPC communication protocol. However, although the embodiments as discussed herein may be implemented in accordance with SPC protocols, the embodiments as discussed herein are not limited to a specific type or definition of a specific type of communication protocol. The embodiments as discussed herein may be implemented in accordance with any suitable type of communication protocol, such as those that utilize PWM-based encoding for communications. Such protocols may be referred to herein as PWM code protocols, and may implement the measurement of time lengths that are varied between one or more edges of a transmitted signal to encode data values based upon a correlation of predetermined time durations to predetermined data values. Such PWM code protocols may encompass the SENT protocol and SPC protocol as of the time of this writing, but may additionally or alternatively encompass any other suitable communication protocols that implement PWM-based encoding that may deviate in one or more ways from the SENT and the SPC protocols as of the time of this writing.

Section I. Signaling schemes for bidirectional communications

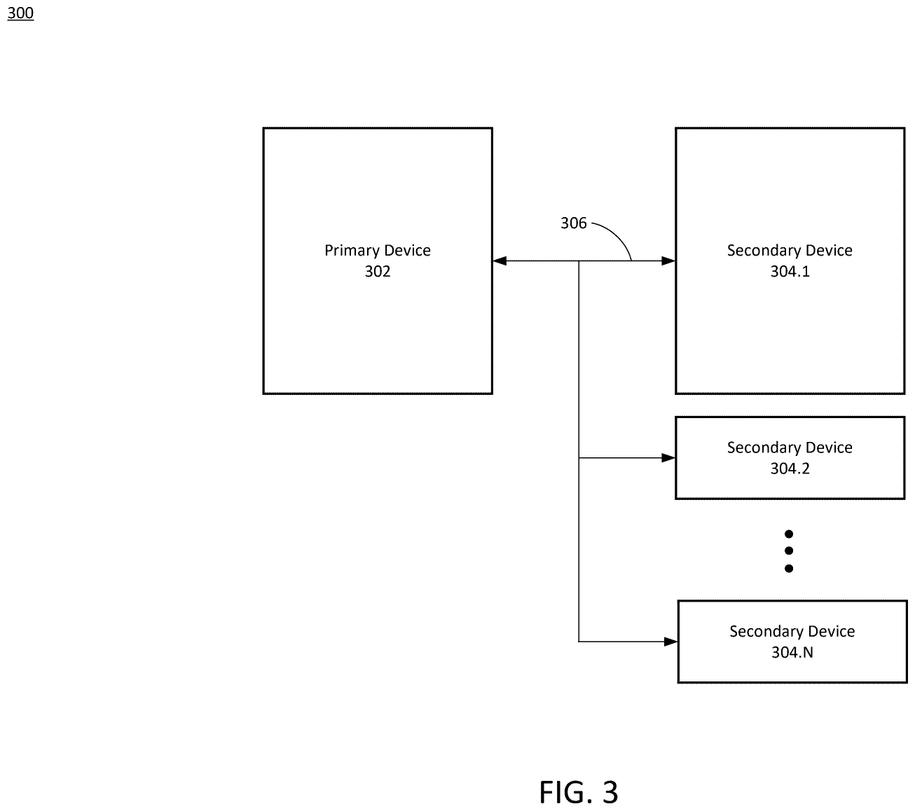

FIG. 3 illustrates an example communication system implementing bidirectional SPC communications, in accordance with one or more embodiments of the disclosure. The communication system 300 as shown in FIG. 3 includes a primary device 302 and any suitable number N of secondary devices 304.1-304.N. The primary device 302 and the secondary devices 304.1-304.N may be communicatively coupled to one another via the communication links 306, which may comprise a communication path and represent any suitable number and/or type of communication links to facilitate the transfer of data in accordance with any suitable number and/or type of communication protocols. For instance, the communication links 306 may comprise wired and/or wireless links, buses, wires, cables, conductive traces, optical connections, etc.

The primary device 302 may be implemented as any suitable type of device, which may perform bidirectional and/or unidirectional communications with each of the secondary devices 304.1-304.N in accordance with any suitable number and/or type of communication protocols. For example, the primary device 302 may be implemented as a microcontroller, a host device, an electronic control unit (ECU), etc. The secondary devices 304.1-304.N may likewise be implemented as any suitable type of device, which may perform bidirectional and/or unidirectional communications with the primary device 302 in accordance with any suitable number and/or type of communication protocols. For example, the secondary devices 304.1-304.N may be implemented as any suitable type of sensors, each being configured to generate sensor data in accordance with respective measurements of physical values such a magnitude and/or direction of a magnetic field, an applied force, a measured angle or measured torque of a rotatable shaft, a temperature, a liquid level measurement, humidity, etc.

Again, the primary device 302 and each of the secondary devices 304.1-304.N may communicate with one another via the communication links 306 using any suitable number and/or type of communication protocols. Such communication protocols may include, for instance, SPC communication protocols, which may include the various enhancements to the SENT protocol as well as further enhancements as discussed herein to enable bidirectional data communications. Thus, the communication links 306 may comprise wires implemented in accordance with SPC protocols, such as a GND, VDD, and DATA wires. Additionally or alternatively, when communicating via an SPC communication protocol, the primary device 302 and each of the secondary devices 304.1-304.N may communicate with one another via a synchronous mode of operation (e.g. when only one secondary device 304.1-304.N is present) or via a bus mode of operation (e.g. when more than one secondary device 304.1-304.N is present).

Except as otherwise noted herein, the primary device 302 and each of the secondary devices 304.1-304.N may communicate with one another in accordance with any aspects of the SPC communication protocols and/or the SENT communication protocols, such as those discussed above for instance. Again, the SPC communication protocol may include the use of data transmitted as a series of data bit groups, each including a time-encoded value representing four bits, as is the case for the SENT protocol, or less bits. The embodiments as discussed herein may thus implement the use of any suitable number of bits to encode the data bit groups. For instance, the data bit groups may comprise data nibbles as defined in accordance with the SENT protocol or, alternatively, the data bit groups may comprise a lesser number of bits, such as 3 or less for example.

The embodiments discussed in further detail herein enable bidirectional communications to be performed between the primary device 302 and the secondary devices 304.1-304.N in accordance with the SPC communication protocol. Such bidirectional SPC communications may include, for instance, the primary device 302 transmitting and/or receiving data from any of the secondary devices 304.1-304.N, as well as any of the secondary devices 304.1-304.N transmitting and/or receiving data from the primary device 302. To do so, SPC communications as discussed herein may still be implemented, but the SPC communication protocol may be modified in various ways that are recognized by the primary device 302 and the secondary devices 304.1-304.N to achieve bidirectional communications.

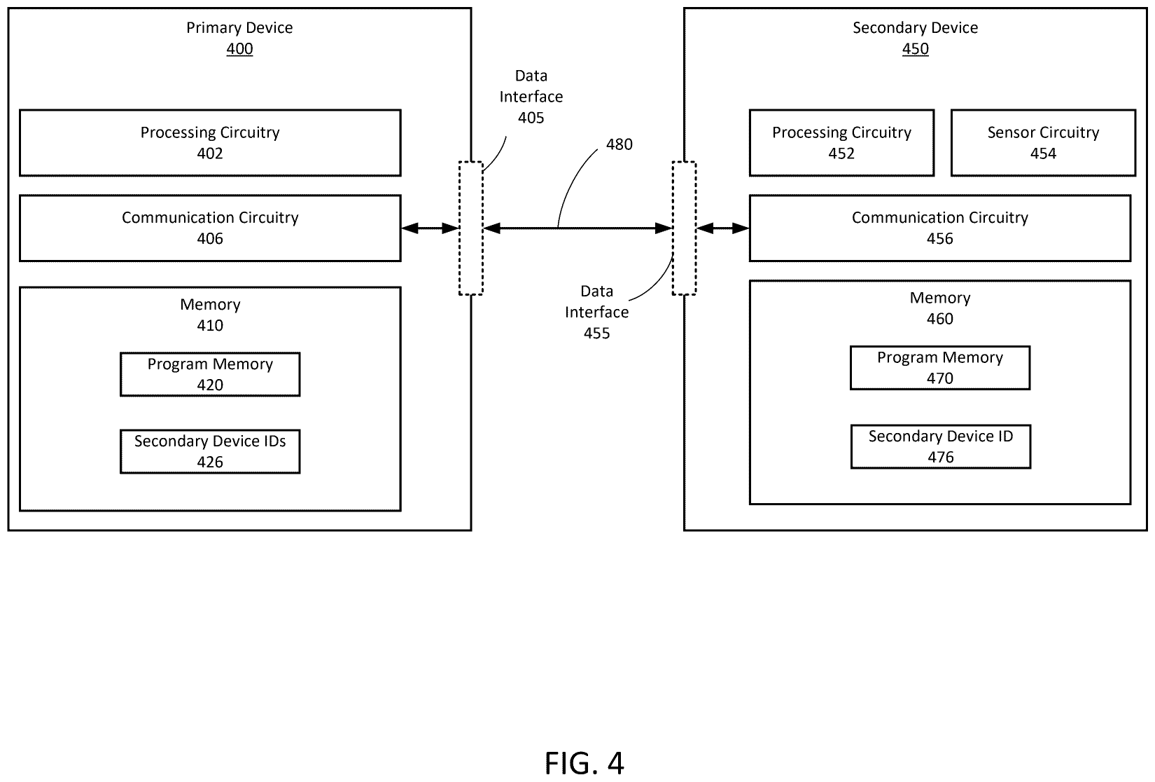

To do so, reference is now made to FIG. 4, which illustrates additional detail with respect to the example communication system as shown in FIG. 3, in accordance with one or more embodiments of the disclosure. The primary device 400 may be identified with the primary device 302 as shown in FIG. 3, and the secondary device 450 may be identified with any one of the secondary devices 304.1-304.N as shown in FIG. 3. The communication links 480 may be identified with the communication links 306 as shown in FIG. 3, which again may represent a communication path. Thus, the primary device 400 and the secondary device 450 may communicate with one another as discussed in further detail herein via the communication links 480, which may include the use of a bidirectional SPC communication protocol for instance.

Thus, the primary device 400 may include processing circuitry 402, communication circuitry 406, and a memory 410. The secondary device 450 may likewise include processing circuitry 452, communication circuitry 456, and a memory 460, which may be configured to operate in a similar manner as the processing circuitry 402, communication circuitry 406, and memory 410, respectively, of the primary device 400, as further discussed below, excepting for other differences in their operation as discussed herein.

The secondary device 450 may additionally include sensor circuitry 454, which may include any suitable number and/or type of sensors and/or sensor elements. Thus, the sensor circuitry 454 may be configured to generate sensor data in accordance with any suitable physical measurement based upon the configuration and type of the secondary device 450. The sensor data generated via the sensor circuitry 454 may be transmitted to the primary device 400 in accordance with the SPC protocol.

Each of the primary and secondary devices 400, 450 may include additional, fewer, or alternate components than those shown in FIG. 4, which are provided by way of example and not limitation. For instance, the memory 410, 460 of the primary and secondary devices 400, 450 may include one or more different types of memory such as non-volatile memory (e.g. an EEPROM), volatile memory, etc. The program memories 420, 470, the secondary device IDs 426, and/or the secondary device ID 476 may be stored in their respective memories 410, 460, which again may comprise one or more non-volatile memories (e.g. an EEPROM), volatile memories, etc. Moreover, although shown as separate components, any of the components of the primary and secondary devices 400, 450 may be integrated or otherwise combined with one another.

The processing circuitry 402, 452 may comprise any suitable number and/or type of hardware components. For instance, the processing circuitry 402, 452 may be implemented as any suitable number and/or type of dedicated hardware components such as a microcontroller, an application specific integrated circuit (ASIC), a field programmable gate array (FPGA), a system on a chip (SoC), dedicated logic and/or other circuitry, a multi-processing unit (MPU), an application processing unit (APU), a hardware-based state machine, etc. The processing circuitry 402, 452, and the program memories 420, 470 are illustrated in FIG. 4 as separate components. However, this is for ease of explanation, and it is understood that the processing circuitry 402, 452 and the program memories 420, 470, respectively, may, in some embodiments, comprise a single component.

The embodiments as described in further detail herein may be implemented via software, hardware, or combinations of these. For example, the processing circuitry 402, 452 may be implemented as one or more processors and/or cores, which may execute computer-readable instructions stored in the respective program memories 420, 470 to perform any of the various functions as discussed in further detail herein. Alternatively, the embodiments described in further detail herein may be implemented via the processing circuitry 402, 452 of each respective device 400, 450 in accordance with hardware-based implementations.

The communication circuitries 406, 456 may be implemented as any suitable hardware components that enable communications between the primary and secondary devices 400, 450, as further discussed herein, via the data interfaces 405, 455 and the communication links 480. Thus, the communication circuitries 406, 456 may perform bidirectional communications by transmitting and receiving data (e.g. SPC frames) in accordance with any suitable number and/or type of communication protocols, such as those discussed herein. To do so, the communication circuitries 406, 456 may comprise hardware components, software components, or combinations of these, which are typically associated with components configured to perform data communications.

For example, the communication circuitries 406, 456 may comprise any suitable number of ports, drivers, open drain or push-pull output stage architectures used in accordance with SPC communications, transmit and/or receive buffers, switches, etc. Additionally or alternatively, the communication circuitries 406, 456 may comprise any suitable number and/or type of dedicated hardware components such as a microcontroller, an application specific integrated circuit (ASIC), a field programmable gate array (FPGA), a system on a chip (SoC), dedicated logic and/or other circuitry, a multi-processing unit (MPU), an application processing unit (APU), a hardware-based state machine, etc. The communication circuitries 406, 456 may be implemented as one or more processors and/or cores, which may execute computer-readable instructions stored in the respective program memories 420, 470 to perform any of the various functions as discussed in further detail herein. The communication circuitries 406, 456 may be separate components or integrated as part of their respective processing circuitries 404, 452, in various embodiments.

Although referred to herein as “circuitry,” the processing circuitry 402, 452 and/or the communication circuitry 406, 456 may perform their respective operations as discussed herein using software, hardware, or combinations of these. For instance, any of the operations performed to implement the bidirectional SPC communications as discussed herein may be performed via the processing circuitry 402, 452 and/or the communication circuitry 406, 456 executing instructions stored in their respective program memories 420, 470, as dedicated hardware components, or as combinations of these.

The data interfaces 405, 455 may be configured to facilitate the transmission and/or reception of data in accordance with any suitable protocols. In an embodiment, each of the data interfaces 405, 455 may represent the physical layer and the accompanying data interfaces used in accordance with any suitable communication protocol and/or standard, such as SPC for example. Additionally or alternatively, the data interfaces 405, 455 may represent any suitable hardware that couples the primary and secondary devices 400, 450 to the communication links 480, such as terminals, pins, ports, etc.

In addition to the program memories 420, 470, the memory 410 may store secondary device IDs 426, whereas the memory 460 may store the secondary device ID 476. The secondary device IDs 426 may comprise an identification of each unique secondary device ID (e.g. a 2-bit value) with which the primary device 400 is configured to communicate. The processing circuitry 404 may access the secondary device IDs 426 to determine how to construct the data frame for an intended secondary device, as discussed in further detail herein. The secondary device ID 476 may comprise an identification of the secondary device ID (e.g. a 2-bit value) with which the primary device 400 is configured to communicate. As noted above, the secondary device ID 476 may uniquely identify the secondary device 450 among several other secondary devices that communicate with the primary device 400. The processing circuitry 452 may access the secondary device ID 476 to determine whether a received data frame (or portion thereof, such as a trigger signal) is intended for the secondary device 450 in accordance with the decoded value of the trigger signal or other received data, as discussed in further detail herein.

The primary devices 400, 450 may communicate with one another in accordance with a conventional SPC communication protocol. This may include the transmission of the trigger pulse by the primary device 400, as discussed above, which causes the secondary device 450 to transmit sensor data back to the primary device 400. This mode of operation may be referred to herein as a standard or default mode of communications, which may include the use of any of the aspects of the SENT and/or SPC protocols as discussed above to facilitate such communications. During the standard mode of communications, the primary device 400 primarily receives data, whereas the secondary device 450 primarily transmits data. Thus, during the standard mode of communications, the primary device 400 may be alternatively referred to as operating in a receiving mode of operation, whereas the secondary device 450 may be alternatively referred to as operating in a transmitting mode of operation.

Additionally, the embodiments as further discussed below may enable the primary and secondary devices 400, 450 to switch from the standard mode of communications to an alternate mode of communications. During this alternate mode or communications, the primary device 400 primarily transmits data, whereas the secondary device 450 primarily receives data. Thus, during the alternate mode or communications, the primary device 400 may be alternatively referred to as operating in a transmitting mode of operation, whereas the secondary device 450 may be alternatively referred to as operating in a receiving mode of operation.

Thus, bidirectional data communications may be achieved between the primary and the secondary devices 400, 450 by way of each of the devices 400, 450 switching between the standard and the alternate modes of communications. The primary and secondary devices 400, 450 may operate in a default or predetermined mode of operation that may initially include the standard mode of communications. However, the primary device 400 may control the switch from the standard mode of operation to the alternate mode of operation based upon any suitable conditions being met, such as when a sensor needs to be reconfigured or other data needs to be transmitted to the sensor for any suitable purpose. Thus, and as further discussed below, the primary device 400 may use any suitable type of signaling scheme to encode a trigger signal, which represents an alternate mode of communication command, thereby causing the secondary device 450 to switch to the alternate mode of operation. As further discussed herein, this may include the implementation of any suitable aspects of the conventional SPC communication protocol and/or encoding schemes that deviate from the conventional SPC communication protocol. In any event, the alternate mode of communication command, when received and recognized by the secondary device 450, acts as a trigger to switch the secondary device 450 to the alternate mode of operation. When a data frame is transmitted by the primary device 400 that does not include the alternate mode of communication command, the primary and secondary devices 400, 450 may otherwise communicate with one another in accordance with the standard mode of communications (e.g. a conventional SPC communication protocol).

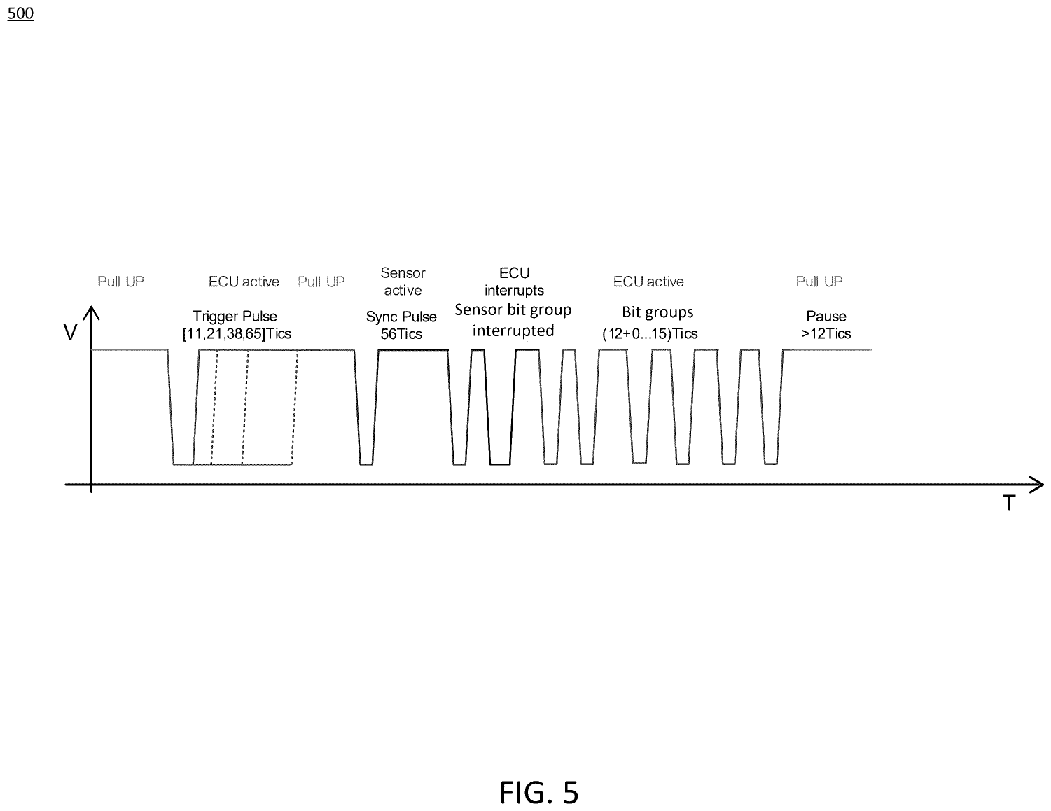

Various examples of the alternate mode signaling schemes, which are used to encode the alternate mode of communication command, are discussed in further detail below with respect to FIGS. 5-14. Each of these schemes are discussed with respect to the voltage state of any suitable portion of a communication path that is used to communicatively couple the primary and secondary devices 400, 450 to one another. For instance, the communication link 480 may include high and low reference voltage lines (e.g. buses or wires), which may be denoted as V (e.g. 3V, 5V, etc.) and GND (0V) for example. The communication link 480 may also include a DATA line (e.g. a bus or wire), which has a voltage level that may be modulated (by the first and the secondary devices 400, 450) between the high and low reference voltage values associated with the high and low reference voltage lines, respectively.

The voltage level of the DATA line may thus be controlled by either the primary or the secondary device 400, 450 in different ways and at different stages of SPC communications, as discussed in further detail below. This may be enabled, for example, via the communication circuitry 406, 456 and data interfaces 405, 455 of the respective first and secondary devices 400, 450, which may comprise any suitable combination of hardware components to do so (e.g. an open drain, a push-pull output stage, etc.), including known components used for this purpose. The embodiments as further discussed below with respect to FIGS. 5-14 may be provided with respect to the voltage state of the DATA line, for example, by way of example and not limitation. It is noted that in some of these embodiments, which are explained in further detail below, the voltage level on the DATA line may deviate from those typically used for the standard SPC communication protocol voltage values. However, in other embodiments, the voltage level on the DATA line may remain in accordance with those implemented for standard communication protocol voltage values.

In any event, and as discussed in further detail below, the primary device 400 may modify any suitable portions of the SPC protocol in a predetermined manner that is recognized by the secondary device 450. Again, this functions to trigger the secondary device 450 to switch to the alternative mode of communications. In each of the FIGS. 5-14, the communications of the primary and the secondary devices 400, 450 are denoted as “ECU active” and “sensor active,” respectively. However, this is by way of example and not limitation and, as noted above, the primary and the secondary devices 400, 450 may be implemented as any suitable type of device. Furthermore, in each of the FIGS. 5-14, the primary and secondary devices 400, 450 are described as performing various communicative actions that modulate the state of the DATA line as shown. In each of these scenarios, unless otherwise noted, such communicative actions may be performed by the primary device 400 via the data interface 405 and/or the communication circuitry 406, and may be performed by the secondary device 450 via the data interface 455 and/or the communication circuitry 456. Such communicative actions may also include the primary and secondary devices 400, 450 transmitting and receiving data from one another, as further described herein.

Turning now to FIG. 5, the primary and secondary devices 400, 450 may begin in the standard mode of operation, which includes the primary device 400 transmitting the trigger pulse (also referred to herein as a trigger signal) to the secondary device 450. The trigger signal may be received by the secondary device 450 via the data interface 455 and the communication circuitry 456, and the processing circuitry 452 may measure the duration of the trigger signal. It is assumed in this case that the secondary device 450 is the intended target device, and thus the length of the trigger pulse is decoded by the secondary device 450 and is assumed to match the secondary device ID 476. In response, the secondary device 450 transmits the sync pulse via the data interface 455 and the communication circuitry 456. The secondary device 450 then transmits the sensor data via the data interface 455 and the communication circuitry 456 as a series of data bit groups in accordance with the SPC protocol.

However, during the transmission of the sensor data bit groups, the primary device 400 may interrupt the transmission of the sensor data transmission by pulling down the DATA line. As noted above with respect to FIG. 2, The secondary device 450 may monitor the DATA line (or the current consumption, as noted above) to detect this interruption and, in response, stop its current transmission and enter into the alternate mode of operation to subsequently receive data from the primary device 400. For instance, the secondary device 450 may determine that the DATA line has remained low during a sensor bit group transmission for a period of time exceeding a threshold time period instead of returning to the default high voltage state (e.g. V), and thus enter the alternate mode of operation. After this process has completed, the primary device 400 may then transmit data in accordance with the SPC protocol, which may be identical to the protocol that is otherwise used by the secondary device 450 to transmit sensor data to the primary device 400.

This alternative communication mode triggering scheme may allow for the operation of the primary and secondary devices 400, 450 in the synchronous mode or the bus mode, as the trigger pulse may still be implemented in the same manner as the conventional SPC communication protocol. And, like, the scheme described with respect to FIG. 2, this scheme also advantageously allows the SPC bus mode to remain unchanged as long as no interrupt appears. However, unlike the scheme described with respect to FIG. 2 during which the sync pulse transmission is interrupted, by interrupting the sensor data bit group transmission as shown in FIG. 5, the primary device 400 may still adapt to the time base of the secondary device 450 as the sync pulse is still transmitted by the secondary device 450. However, the scheme as shown in FIG. 5 still requires current consumption during the interruption of the sensor data bit groups.

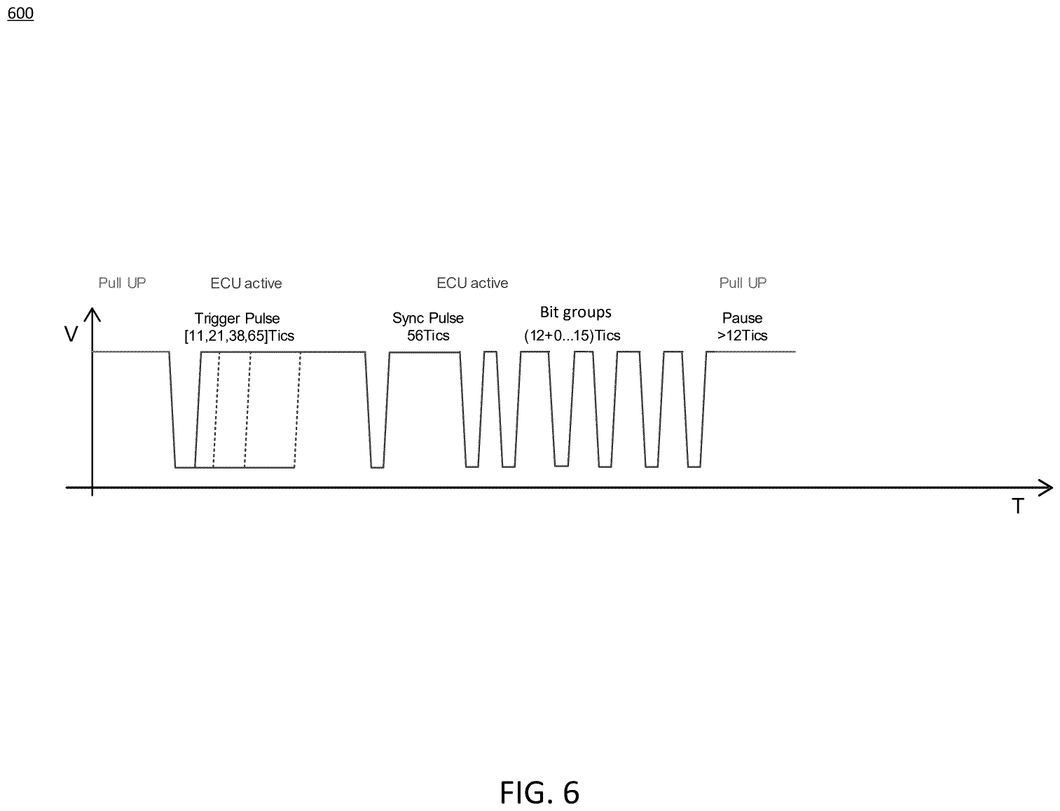

Thus, the remaining FIGS. 6-14 are directed to additional embodiments that may be used by the primary device 400 as alternative communication mode triggering schemes. In each of these embodiments, the transmissions of the secondary device 450 are not interrupted. Instead, in each scenario, which are discussed in greater detail below, the processing circuitry 402 is configured to generate a data frame or portions thereof, which is then transmitted to the secondary device 450 via a communication path via the communication circuitry 456.

Additionally, and unless otherwise noted below, in each of the scenarios as described with respect to FIG. 6-14, the communication circuitry 406 is configured to transmit the data frame (or portions thereof) over the communication path by modulating the DATA line that may form part of the communication links 480, for example, as discussed herein. Moreover, and unless otherwise noted below, in each of the scenarios as described with respect to FIG. 6-14, when data transmissions are proffered by the secondary device 450, the communication circuitry 456 is configured to transmit the data by modulating the DATA line that may form part of the communication links 480, for example, as discussed herein.

Moreover, and as further discussed below, the trigger signal as discussed with respect to FIGS. 6-14 may have any suitable number of edges, each having a respective direction. That is, and as discussed in further detail below, the trigger signal may include one or more rising edges and one or more falling edges. The rising edges may be identified as having one direction, e.g. a slope having a temporal direction that defines such edges as transitioning from a lower to a higher voltage value. Each of the rising edges of the trigger signal may be considered as having the same direction as one another, excepting for driver and/or timing tolerances. The falling edges may be identified as having another, different direction, e.g. a slope having a temporal direction that defines such edges as transitioning from a higher to a lower voltage value. Each of the falling edges of the trigger signal may also be considered as having the same direction as one another, excepting for driver and/or timing tolerances. Thus, the rising and falling edges may alternatively be described herein as edges having a specific direction, with the rising edges having the same direction as one another and the falling edges having another, different direction that is the same as one another, but is different than the direction of the rising edges.

Referring first to FIG. 6, the data frame may thus comprise a trigger signal (e.g. the trigger pulse in this example) and a plurality of data bit groups as shown. The trigger pulse and the data bit groups may each be transmitted in accordance with any suitable communication protocol, such as the SPC protocol, for example. This may be the same SPC protocol used by the secondary device 450 to transmit data bit groups in accordance with the standard communication mode, as discussed herein.

Additionally, the data frame may comprise a synchronization (sync) pulse, which has a predetermined duration of 56 tics as shown. Again, the conventional SPC communication protocol implements the sync pulse as a transmission from the secondary device 450 to the primary device 450 in accordance with the standard communication mode, as discussed herein. The sync pulse has a defined length in terms of the sensor time base, which is referenced from the sensor clock frequency, and is expressed as a length of 56 tics, which is then received by the primary device 400. For the standard communication mode, the primary device 400 measures the length of the 56 tic sync pulse to then calibrate the time base of the primary device 400 to that of the secondary device 450. For example, the primary device 400 may measure the length of the sync pulse and determine that the 56 tics used by the secondary device 450 are 10% higher, 5 % lower, etc., than that of the clock implemented by the primary device 400 used to define the time base by the primary device 400. Thus, upon calibrating the time base reference at the primary device 400, it is ensured that the time base of the primary and the secondary devices 400, 450 are synchronized with one another (e.g. match) despite deviations between the clocks used at each device.

This time base synchronization process is part of the SPC communication protocol and is generally known. However, the embodiments described herein may enable the primary device 400 to transmit its time base to the secondary device 450 as part of the alternative communication mode. To do so, the primary device 400 may transmit the sync pulse in the same manner as is typically performed by the secondary device 450. Thus, the processing circuitry 402 is configured to generate the time base reference of the primary device 400 based upon its clock frequency, which may include any suitable clock which is used for SPC communications. In this scenario, the primary device 400 transmits the sync pulse having a length of 56 tics expressed in terms of its own time base, which is then received by the secondary device 450. The secondary device 450 may then adjust its own time base to match that of the primary device 400, which is then used by the secondary device 450 to decode the transmitted data middles.

Additionally, the use of the trigger signal may be modified in this scenario from that used in accordance with the conventional SPC communication protocol. For example, the trigger signal may still represent one of several different predetermined time lengths (e.g. 11, 21, 38, or 65 tics as shown), which may be identified with time-encoded values representing different bus codes. As noted above, these different bus codes may encode a sensor address that is used by each receiving sensor to determine whether sensor data is being requested from that particular sensor. Additionally or alternatively, the different predetermined time lengths may be identified with time-encoded values representing different sensor configuration data. However, in accordance with the present embodiments, one or more of the bus codes of the trigger signal may be reserved as a command to instruct the secondary device 450 to enter into the alternative mode of communication and thus receive the data bit groups in the transmitted data frame following the trigger signal.

In other words, the trigger signal may indicate to the secondary device 450 (e.g. via the use of one of the bus codes) to transition from a transmitting mode of operation (e.g. the standard communication mode) to a receiving mode of operation (e.g. the alternative communication mode) to receive data encoded in the plurality of data bit groups in the communication frame. Thus, the length of time of the trigger signal may be selected by the primary device 400 from among a set of different predetermined lengths of time. One of these predetermined lengths of time may be reserved and identified by the primary and secondary devices 400, 450 as being associated with the alternative communication mode command, whereas the other predetermined lengths of time may represent respective encoded device addresses or respective device configuration data.

The different bus codes encoded by the length of the trigger signal may be used in different ways depending upon the particular application. For instance, a synchronous bus mode of operation may include the secondary device 450 as the only device communicating with the primary device 400. In this scenario, one of the predetermined lengths of time (e.g. the shortest tic value) may be reserved as an indication to the secondary device 450 that sensor data is being requested. Continuing this example, any other ones of the predetermined lengths of time of the trigger signal may then be reserved as the alternative communication mode command.

As an alternate scenario, a bus mode of operation may be implemented. In this scenario, the alternative communication mode command may be communicated in various ways depending upon the particular application and the number of secondary devices 450. For example, one of the bus codes encoded by the length of the trigger signal may be reserved as the alternative communication mode command, with the other bus codes being identified with different secondary device IDs. In accordance with such embodiments, one less secondary device 450 may be supported in bus mode, as one of the bus codes is “sacrificed” for the use of the alternative communication mode command.

In accordance with such embodiments, when the primary device 400 requests for a specific secondary device 450 to transition to the alternative communication mode to receive data, the device ID for that secondary device may be encoded as part of the transmitted data bit groups. For example, for bus mode operations, several secondary devices 450 are coupled to the same communication links 480 (and to the primary device 400 via this link). Thus, when the primary device 400 transmits the trigger signal as part of the data frame, the trigger signal is received by every secondary device 450 coupled to the same bus. As a result, each secondary device 450 may receive and interpret the alternative communication mode command and, in response, temporarily enter into the receiving mode of operation. In this state, each secondary device 450 may receive the data bit groups, which may contain time-encoded data representing a specific secondary device ID. In the same manner as described above for the use of the trigger signal, each secondary device 450 may then decode the time-encoded data and compare this value to the stored device ID to determine whether the alternative communication mode command is intended for that secondary device 450. If so, then the secondary device 450 may continue to operate in the alternative communication mode to receive data from the primary device 400 in accordance with the SPC communication protocol. Otherwise, the secondary device 450 may ignore the command and switch back to the standard communication mode.

As another example, the number of supported secondary devices 450 may be further reduced to facilitate a bus coding scheme that enables each secondary device 450 to be instructed with respect to its current communication mode. For instance, if two secondary devices 450 are implemented as part of a bus mode of operation with the primary device 400, then each bus code may represent the combination of a secondary device ID and the communication mode for that secondary device. As an illustrative example, if two sensors having IDs of 00 and 01 are implemented as the secondary devices, then the four bus codes may be represented as follows by each sensor receiving the trigger signal:
11 tics: sensor 00, standard communication mode (e.g. a transmit address);
21 tics: sensor 00, alternative communication mode (e.g. a receive address);
38 tics: sensor 01, standard communication mode (e.g. a transmit address); and
65 tics: sensor 01, alternative communication mode (e.g. a receive address).

In this way, the trigger signal may encode data via the use of the bus codes that not only identifies the intended recipient of the data frame, but simultaneously instructs each sensor with respect to its communication mode. The embodiments as discussed with respect to FIG. 6 advantageously enable the SPC bus mode to remain unchanged as long as no double pulse appears (e.g. the trigger pulse and sync pulse). Additionally, because the primary device 400 does not need to interrupt the secondary device 450 transmission, the current increase as discussed with respect to FIG. 5, which requires the primary device 400 to pull down the DATA line, are avoided. And because this scheme does not require the interruption of the secondary device transmission, latency is avoided, resulting in a shorter transmission time. However, the present embodiments also require that the secondary device 450 adapt to the timing of the primary device 400 using the sync pulse signal.

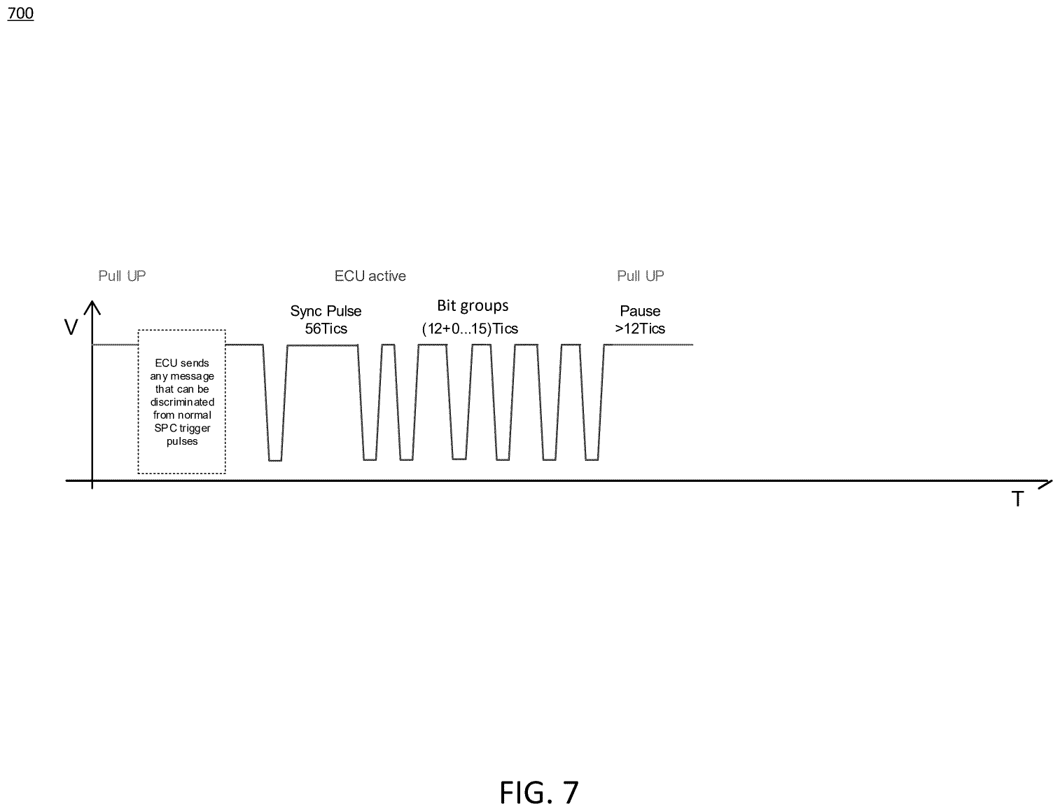

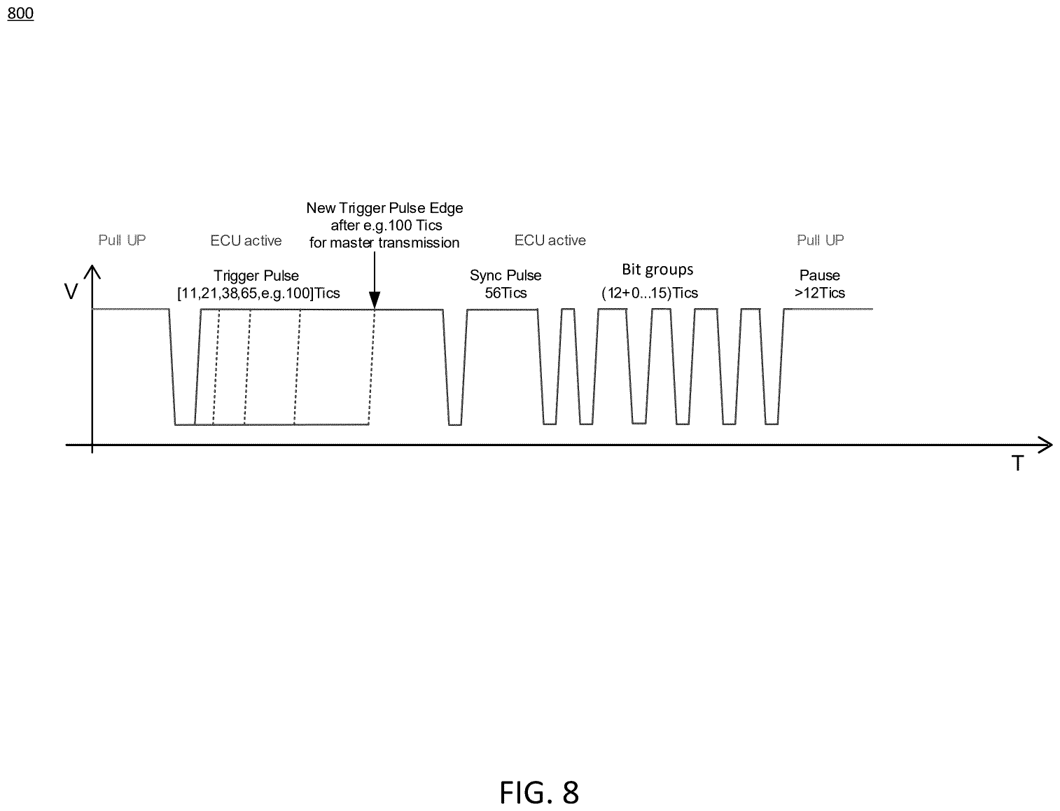

Turning now to FIG. 7, embodiments include the primary device 400 transmitting the data frame to include any suitable type of message, which may then be interpreted by the secondary device 450 as the alternative communication mode command. In this scenario, the primary device 400 may, for instance, begin the transmission of the data frame with any suitable sequence that infringes on the manner in which the SPC communication protocol defines the SPC trigger pulse. This message may include a modification of the trigger signal to deviate from the defined usage of the trigger pulse in accordance with the SPC protocol, as discussed in further detail below with respect to FIG. 8-12 for example. The message used for the purpose of instructing the secondary device 450 to enter into the alternative communication mode is not limited to the modification of the trigger pulse, and may comprise additional or alternative messages, sequences, encoded data, DATA line modulation, etc. However, simple variants of the trigger pulse may be particularly useful to specify the alternative communication mode command, as the intention of SPC is to support a simple and robust implementation on the transmitter and receiver side.

In any event, the secondary device 450 may be configured to recognize and differentiate such a command message to then enter into the alternative mode of communication and thus receive the data bit groups in the transmitted data frame following this message. It is noted that although the primary device 400 may transmit the message in a manner that deviates or “breaks” the SPC protocol, the subsequently transmitted data bit groups may still be sent in accordance with the SPC protocol. Thus, the modifications made to a secondary device 450 to ensure bidirectional communications may be less complex, e.g. updating the firmware and/or software of such a device.

FIG. 8 illustrates an example implementation of a modified trigger pulse that may be used to encode the alternative communication mode command to the secondary device 450. As discussed above with respect to FIG. 6, the scheme as shown in FIG. 8 may also implement one of the predetermined lengths of the trigger signal to provide the alternative communication mode command to the secondary device 450. However, in the embodiment as shown in FIG. 8, the length of time of the trigger signal that indicates to the secondary device 450 to transition to the receiving mode of operation is greater than the other predetermined lengths of time.

That is, instead of replacing one of the SPC-defined predetermined lengths of time of 11, 21, 38, and 65 tics, the scheme as shown in FIG. 8 extends the overall length of the trigger pulse to provide the trigger signal as shown. In this way, the length of time of the trigger signal that indicates to the secondary device 450 to transition to the receiving mode of operation is greater than the other predetermined lengths of time that are defined in accordance with the SPC communication protocol (e.g. of 11, 21, 38, and 65 tics). In doing so, an additional predetermined length of time is used to encode the alternative communication mode command transmitted to the secondary device 450. This additional predetermined length of time is shown in FIG. 8 as 100 tics in length, but may be any suitable length that exceeds the maximum length of time defined by the SPC commutation protocol (e.g. 65 tics). Additionally, although one additional predetermined length of time is used is used in the scheme as shown in FIG. 8, this is by way of example and not limitation, as the trigger signal may be extended to any suitable length to include any suitable number of additional predetermined lengths of time, each being identified with a respective command, a secondary device address, configuration data, etc.

The scheme as shown in FIG. 8 may thus work in a similar manner as the scheme discussed in FIG. 6 and thus share the same advantages. Thus, the scheme as shown in FIG. 8 may also work in accordance with a synchronized or a bus mode, although it may be particularly advantageous to use this scheme with a bus mode given the extended length of the trigger signal. And, as noted above, for the scheme as shown in FIG. 8, the primary device 400 may also transmit the remainder of the data frame (e.g. the sync pulse and data bit groups) in accordance with the SPC communication protocol (e.g. identical to that used by the secondary device when transmitting in the standard communication mode), despite the trigger signal violating the SPC protocol. Moreover, this scheme may be particularly useful when the receive mode activation is a rare case during normal operation of the sensor, as in this case the longer duration for the additional trigger signal code does not significantly impact the channel capacity. For instance, bidirectional communications may be implemented using an initial startup phase to exchange cryprographic data for secured communciations. As another example, such a scheme may be particularly useful for the activation of additional self test time windows, during which an application may allow the sensor to be offline for some time (e.g. for a sensor in a vehicle drive train when the vehicle is stopped or driving slowly).

For instance, and as noted above with respect to the scheme of FIG. 6, each secondary device 450 may receive and interpret the alternative communication mode command and temporarily enter into the receiving mode of operation. The data bit groups for the scheme as shown in FIG. 8 may also contain time-encoded data representing a specific secondary device ID, and each secondary device 450 may then decode the time-encoded data to determine whether the alternative communication mode command is intended for that device. However, the use of the extended trigger signal in this way allows for four or more secondary devices to be implemented in the bus mode instead of the maximum of three as discussed for the scheme of FIG. 6.

As another example, the bus codes encoded by the predetermined lengths of the trigger signal may be implemented to support additional functionality depending upon the particular configuration of secondary devices used in the bus mode. As an illustrative example, in the bus mode of operation, there may be four sensors, with three being configured as “standard” sensors and thus only transmit data (e.g. only operate in the standard communication mode). The remaining sensor may be configured to operate in either the standard or the alternative communication mode as discussed herein. In this scenario, three of the bus codes (e.g. with lengths of 11 tics, 21 tics, and 38 tics) may be used in accordance with the standard SPC protocol to receive sensor data from the three standard sensors corresponding to these sensor addresses. However, the fourth and fifth bus codes (e.g. with lengths of 65 tics and 100 tics) may be reserved as commands to indicate to the fourth sensor to operate either in the standard communication mode (e.g. as a transmit address) or to operate via the alternative communication mode (e.g. as a receive address), respectively.

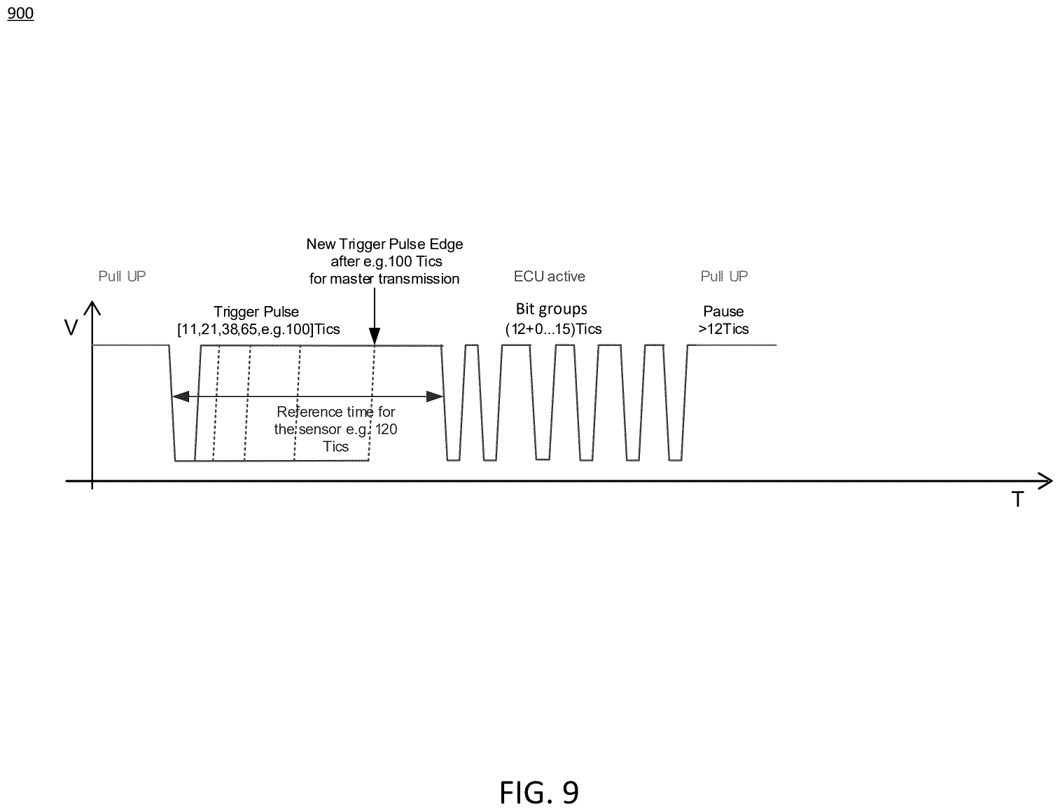

Referring now to FIG. 9, the schemes as discussed above with respect to FIGS. 6 and 8 may be further modified to eliminate the need for the primary device 400 to transmit the synchronization (sync) pulse. That is, in the embodiments discussed in further detail below, the primary device 400 may still transmit its time base reference, but do so in an alternative manner that deviates from the use of the predetermined sync pulse length as defined by the SPC communication protocol. As noted above, the secondary device 450 may still use the time base reference transmitted by the primary device 400 to calibrate its time base (in the same manner as usually performed by the primary device 400 in accordance with the standard SPC communication protocol) to then decode the time-encoded values represented by the length of the data bit groups transmitted by the primary device 400.

Thus, irrespective of how the primary device 400 transmits its time base reference, the processing circuitry 402 is configured to generate the time base reference based upon its clock frequency. Again, this clock frequency may include any suitable clock for which the communication as discussed herein between the primary and secondary devices 400, 450 is based, and may have any suitable frequency for this purpose. For example, the time base reference may be expressed as a length of time in terms of any suitable number of tics, which may be predefined and known to both the primary and the secondary devices 400, 450. Thus, when the primary device 400 transmits the sync pulse, the time base reference may be encoded as the 56 tic length of the sync pulse as discussed above.

However, the alternative communication mode embodiments as discussed herein may also encode the time base reference of the primary device 400 in any other suitable manner, which may include a length of time in terms of tic values that deviate from 56 tics. For example, and referring now back to FIG. 9, the primary device 400 may transmit the trigger pulse to additionally encode its time base reference. The encoded time base reference transmitted in this manner may form any one of the bus codes represented by the different predetermined lengths of the trigger pulse or, as shown in FIG. 9, be encoded as a length of time that exceeds the standard SPC protocol maximum defined value of 65 tics. Thus, the time base encoding scheme as shown in FIG. 9 may be adapted as part of that as discussed above with respect to FIG. 6, or as a further extension of the length of the trigger pulse as discussed with respect to FIG. 8.

To do so, an illustrative and non-limiting example is shown in FIG. 9 in which the trigger pulse includes two falling edges and two rising edges. The time-encoded alternative communication mode command is identified as 100 tics. Thus, the time-encoded values of 11, 21, 38, 65, and 100 tics, as the case may be, are measured by the secondary device 450 from the initial falling edge of the trigger pulse to the next rising edge as shown. The time base reference of the primary device 400, however, may be encoded in the trigger pulse as a length of time between the two falling edges as shown in FIG. 9 or, alternatively, between two rising edges (e.g. the first and last rising edges of the trigger pulse or any other defined rising or falling edge pairs, which is not shown in the Figures). For the illustrative example as shown in FIG. 9, the time base reference of the primary device 400 is expressed as a 120 tic length between the two falling edges of the trigger pulse as shown.

In this way, the trigger pulse may function to achieve two purposes of the alternative communication mode configuration in a single transmission. First, assuming that the primary device 400 is instructing the secondary device 450 to enter into the alternative communication mode, the longer 100 tic time length may be used. The secondary device 450 may measure this trigger pulse length from the first falling edge of the trigger pulse as shown, and interpret this 100 tic length as a command to transition to the receiving mode. Second, the secondary device 450 may observe the next falling edge of the trigger pulse and measure this value as 120 tics in this example. The secondary device 450 may then interpret this 120 tic measurement as the time base reference of the primary device 400. As the secondary device 450 is aware of the 120 tic value as the time base in place of the conventional sync pulse length of 56 tics, this enables the secondary device 450 to calibrate its clock frequency to decode data encoded in the data bit groups that are also transmitted by the primary device 400 as part of the data frame, as shown in FIG. 9 and noted above.

In the signaling schemes discussed above with respect to FIGS. 5-9, the alternative communication mode command is realized by modifying the conventional SPC communication protocol trigger pulse or reassigning the bus codes of the conventional SPC communication protocol trigger pulse. In accordance with such embodiments, the trigger signal may also be referred to as a trigger pulse, with the understanding that the trigger signal may be further modified from the conventional SPC trigger pulse as discussed. However, for the embodiments as discussed in further detail below, the alternative communication mode command may be realized by replacing the conventional SPC communication protocol trigger pulse with a trigger signal that may include additional or alternative signaling schemes.

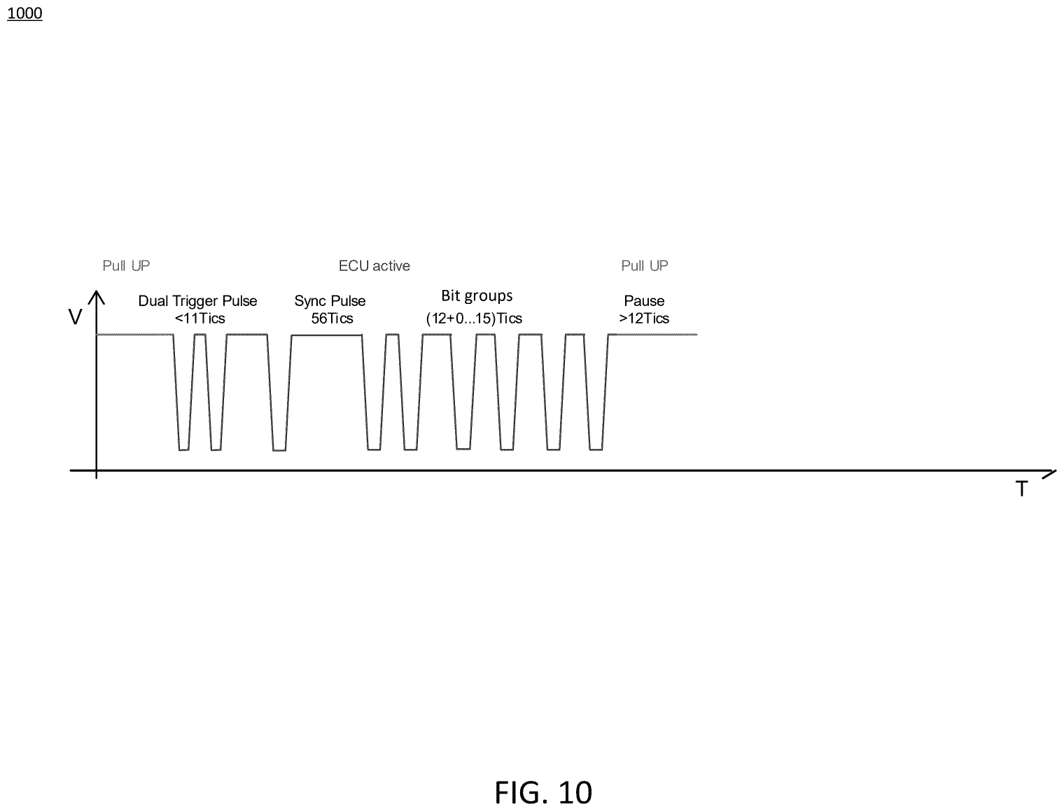

For instance, and turning now to FIG. 10, a signaling scheme is shown to encode the alternative communication mode command, which may be used for a synchronous mode of operation between the primary and secondary devices 400, 450. The trigger signal as shown in FIG. 10 replaces the conventional SPC trigger pulse, and comprises two consecutive pulses. The trigger signal includes two falling edges and two rising edges. Each of the two consecutive pulses has a length that is expressed in terms of a tic time, which is measured by the secondary device 450 between each first rising edge and each first falling edge (for the first pulse) and between the second falling edge and the second rising edge (for the second pulse). Although two consecutive trigger pulses are shown in FIG. 10, this is by way of example and limitation, and any suitable trigger pulse length may be used for this purpose. However, the length of each consecutive pulse may be less than the 11 tic minimum length as defined in accordance with the SPC protocol. In other words, for the scheme as shown in FIG. 10, the trigger signal comprises two consecutive pulses, with a length of time of each one of the two consecutive pulses thus encoding the alternative communication mode command to the secondary device 450. That is, the length of time of each one of the two consecutive pulses indicates to the secondary device 4450 to transition to the receiving mode of operation.

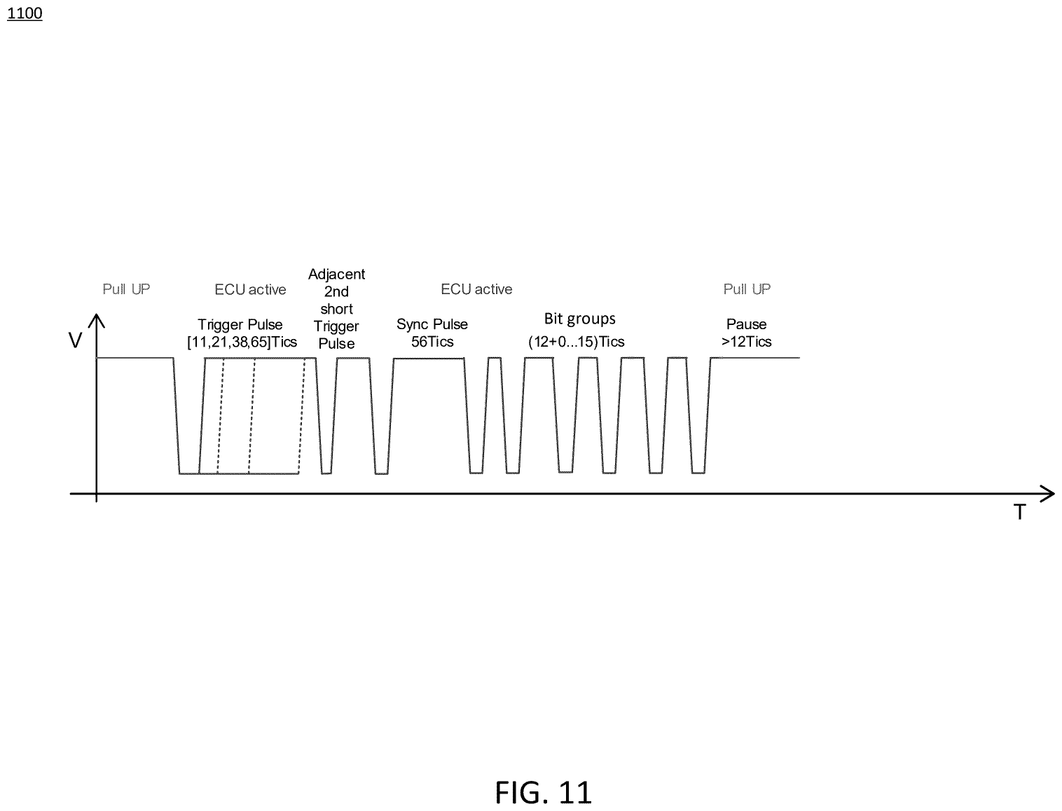

Again, the length of time of each of the two consecutive pulses may be less than a minimum length of time of a trigger pulse defined in accordance with the SPC protocol (e.g. less than 11 tics) or any other suitable threshold value. For instance, the length of time of each of the two consecutive pulses may be 2-10 tics. It is also noted that the length of time of each of the two consecutive pulses may be less than the minimum data bit group transmission time defined in accordance with the SPC protocol, which may be 12 tics. In this way, the length of time of each one of the two consecutive pulses prevents the secondary device 450, as well as other secondary devices that may be coupled to the same bus (as discussed for the bus mode operation below with respect to FIG. 11) from otherwise interpreting the trigger signal as a standard SPC communication protocol trigger pulse that is requesting sensor data (or as the transmission of data). Alternatively, a single pulse may be used instead of the two pulses as shown in FIG. 10, or additional consecutive pulses may be implemented. However, it is noted that the use of at least two consecutive pulses is preferred, as doing so provides robustness to bus noise and increases the prevention of an accidental interpretation of bus noise as an alternative communication mode command.

The embodiments of the scheme as shown in FIG. 10 are likewise advantageous in that the SPC bus mode remains unchanged as long as no double pulse appears, current increase is avoided, and a shorter transmission time is achieved.

Turning now to FIG. 11, the use of one or more shortened pulses to function as the alternative communication mode command may be implemented for bus mode operation in addition to the synchronous mode of operation, as discussed above with respect to FIG. 10. Thus, and as shown in FIG. 10, in lieu of the transmission of the standard SPC trigger pulse, the primary device 400 may transmit a trigger signal that comprises a further trigger pulse that precedes the two (in this example) consecutive short trigger pulses as discussed above with respect to FIG. 10. In this scheme, the initial (preceding) trigger pulse has a length of time that represents an encoded address of the secondary device 450 or configuration data. In other words, the preceding trigger pulse may have a length of 11, 21, 38, or 65 tics, and may represent for example encoded data representing sensor data or configuration data. The preceding trigger pulse may, for instance, conform to the standard SPC communication protocol for the conventional SPC trigger pulse, for instance, as discussed above with respect to FIG. 6.

Thus, the trigger signal in this example includes the initial trigger pulse, which functions to identify the specific recipient secondary device, as well as the dual consecutive pulses, which function as the alternative communication mode command for the specific secondary device. In this way, four or more sensors may be supported in bus mode, as the alternative communication mode command does not occupy one of the bus codes as discussed above, for example, with respect to FIG. 6. This scheme also allows for standard SPC bus mode communications to occur between the primary and the secondary devices 400, 450 via the primary device 400 not including the consecutive short trigger pulses as discussed above with respect to FIG. 10 as part of the trigger signal transmission.

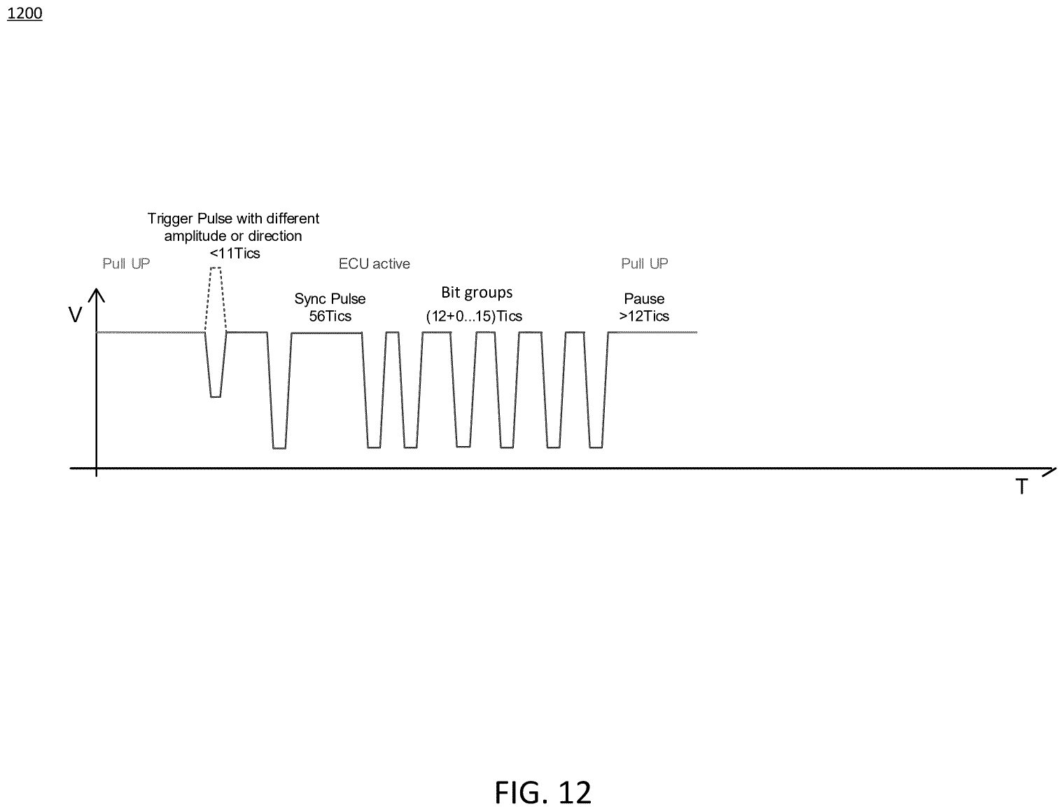

Referring now to FIG. 12, the amplitude and/or polarity (e.g. direction) of the trigger signal may be modified to represent the alternative communication mode command. For example, the trigger signal may comprise one or more pulses having a length that is less than the SPC defined minimum 11 tics, as discussed above with respect to FIGS. 10 and 11. However, the primary device 400 may modulate the voltage level of the trigger signal in this embodiment to exceed or be reduced from the voltage level V of the bus as shown in FIG. 12. Additionally or alternatively, the device 400 may modulate the voltage level of the trigger signal to have a polarity that is the opposite of the other portions of the data frame transmission, as shown in FIG. 12.

The secondary device 450 may measure this voltage level, polarity, and/or the length of the trigger signal and, when these match a predetermined profile, interpret the trigger signal as an alternative communication mode command to transition to the receiving mode of operation. Such embodiments may be implemented, for instance, via the primary device 400 utilizing any suitable output stage that allows for the modulation of the voltage of the bus in accordance with such additional voltage levels, which may form part of the communication circuitry 406 and/or the data interface 405 for instance. Likewise, the secondary device 450 may implement any suitable type of analog-to-digital converters, comparators, or other suitable circuitry to decode the voltage level of the trigger signal in this manner, which may form part of the communication circuitry 456 and/or the data interface 455 for instance.

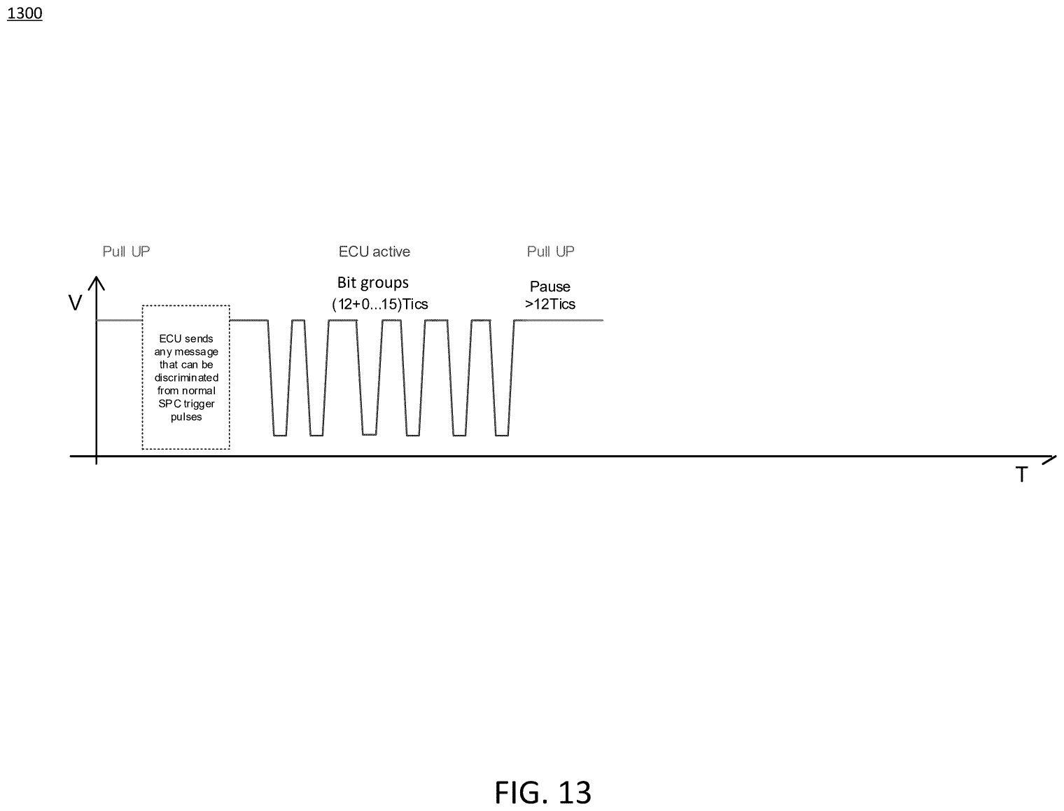

Turning now to FIG. 13, a generalized scheme is shown in which the primary device 400 may transmit the data frame to the secondary device 450 without a sync pulse. This may be implemented, for example, via the transmission of any suitable message that may be discriminated by the secondary device 450 from a trigger pulse and/or a sync pulse that complies with the standard SPC protocol. For instance, the message may comprise the use of the trigger signal that includes an encoded time base of the primary device 400 in lieu of the transmission of the SPC standard 56 tic sync pulse, as shown and discussed with respect to FIG. 9 for instance. As another example, the message may comprise any suitable modification of the trigger pulse and/or the transmitted data frame as discussed herein to encode the time base of the primary device 400. This may include any suitable predetermined scheme that is recognized by the secondary device 450, which may include for example the use of any combination of rising and falling edges of the trigger pulse or other portions of the data frame for this purpose.

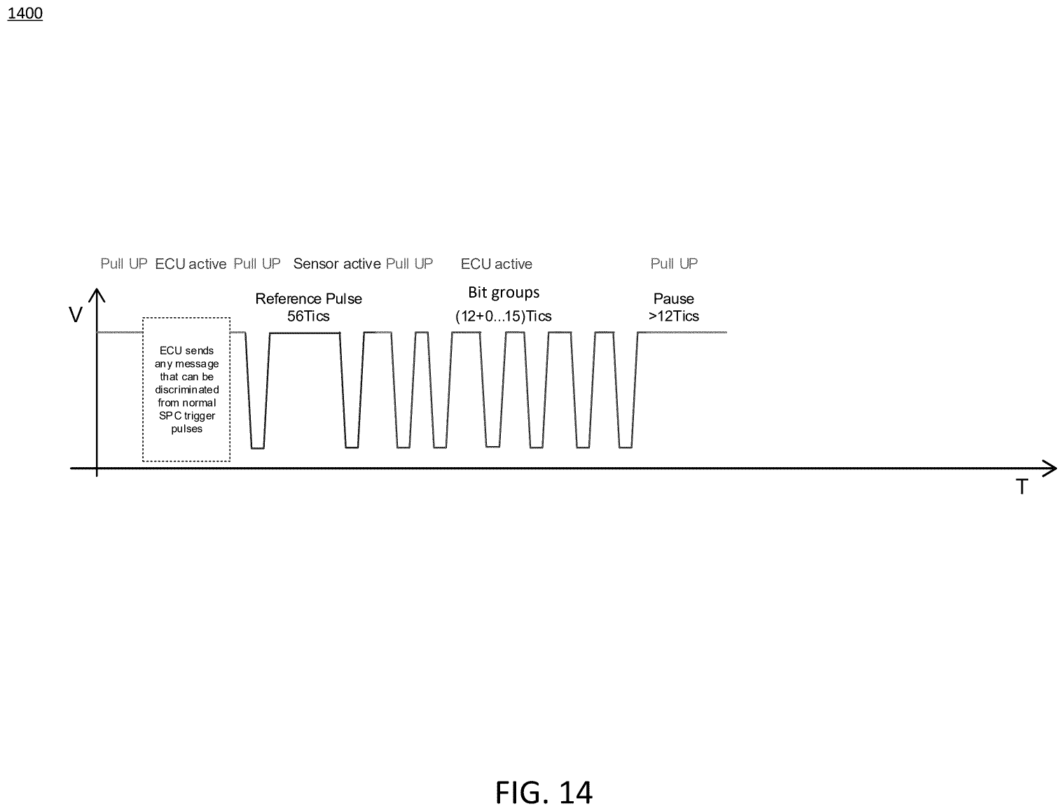

As an additional example, the primary device 400 may use the time base reference transmitted by the secondary device during a prior communication in the standard communication mode to calibrate the time base of the primary device 400. Once this has been performed, subsequent transmissions to the secondary device 450 in accordance with the alternative communication mode may omit the use of the time base transmission and sync pulse, with the primary device 400 encoding the transmitted data bit groups using the previous time base adjustment. Alternatively, the time base and sync pulse transmission via the primary device 400 may be reduced in frequency such that the time base and sync pulse are transmitted periodically (e.g. each n-th message) to enable the secondary device 450 to obtain an updated time base to compensate for clock drifts. In any event, the primary device 400 may transmit the alternative communication mode command in accordance with any of the embodiments as discussed herein in this manner without transmitting the sync pulse or doing so with a reduced frequency instead of in per each transmitted data frame. In some embodiments, the alternative communication mode may be used to periodically request the secondary device 450 to transmit its time base reference so the primary device 400 may update its calibration process for future data bit group transmission encodings. One example of such a request may be the use of the scheme as discussed in further detail below with respect to FIG. 14.

FIG. 14 illustrates an alternate scheme in which the secondary device 450 need not adapt to the time base of the primary device 400. Instead, the primary device 400 may initially transmit any suitable message that functions as the alternative communication mode command to transition the secondary device 450 to the receiving mode of operation. This may include the use of any of the trigger signals adapted for this purpose as discussed herein. However, in accordance with the present embodiments, the secondary device 450 responds to this command by transmitting a sync pulse that encodes the time base of the secondary device 450, as shown in FIG. 14. Again, this sync pulse encodes a time base reference that is based upon the secondary device 450 clock frequency, and may include the use of standard SPC protocol techniques to do so, as discussed herein. For instance, this may be implemented via the communication circuitry 456 transmitting, in accordance with the SPC protocol, its time base reference to the primary device 400, which again is based upon a secondary device 450 clock frequency. In response, the primary device 400 may then calibrate its own time base such that the data bit groups transmitted to the secondary device 450 are encoded based upon the secondary device 450 time base reference. This obviates the need for the secondary device 450 to adapt to the time base of the primary device 400, as was the case in the embodiments discussed above in which he primary device 400 transmitted its encoded time base to the secondary device 450.

In various embodiments as discussed herein, the use of the alternative communication mode command is described with respect to causing one or more of the secondary devices 450 to transition from the transmitting mode of operation to the receiving mode of operation. In accordance with these embodiments, it is assumed that the secondary device 450 is configured to receive, decode, and recognize the alternative communication mode command to effectuate this transition. Thus, such a secondary device 450 may be referred to herein as a bidirectional communication capable device. However, and as noted above, the communication system 300 may include any suitable number of secondary devices 304.1-304.N (e.g. N number of secondary devices 450), which may include standard (e.g. transmit only, i.e. non-bidirectional communication capable) or bidirectional communication capable devices.

Thus, the various schemes used to encode the alternative communication mode command may be leveraged with consideration of the configuration of the communication system 300 and the presence of standard and/or bidirectional communication capable devices. For example, any of the embodiments described herein may be used to implement a broadcast-based alternative communication mode command, which may facilitate a broadcast write command for example to all connected secondary devices. In accordance with such embodiments, each bidirectional communication capable secondary device may receive the same alternative communication mode command indiscriminately, which causes each of these devices to then enter into the receiving mode of operation to decode the data bits transmitted by the primary device 400, which may comprise any suitable type of instructions, a write command, etc. Such embodiments may not require the use of the secondary device ID transmission, as each receiving secondary device 450 may be configured to respond to a predetermined alternative communication mode command. As an illustrative example, the use of the alternative bus code from the embodiments as discussed above with respect to FIG. 6 may be used for this purpose, with the bit groups then encoding information that is interpreted as a broadcast write command by each of the secondary devices 450. In accordance with such embodiments, each standard secondary device 450 may not recognize and thus not respond to the alternative communication mode command.

Alternatively, each bidirectional communication capable secondary device that is part of the communication system 300 may receive a device-specific alternative communication mode command, which causes that particular device to then enter into the receiving mode of operation to decode the data bits transmitted by the primary device 400, which again may comprise any suitable type of instructions, a write command, etc. Thus, such embodiments may be implemented using a specific secondary device address encoding, which again may be part of the trigger signal or encoded as part of the transmitted data bit groups. Additionally, in accordance with such embodiments, each standard secondary device 450 may not recognize and thus not respond to the alternative communication mode command.

In any event, the use of the alternative communication mode command may allow bidirectional communication capable secondary devices to temporarily enter into the receiving mode of operation to receive data. In some embodiments, the secondary device 450 may remain in this receiving mode of operation only for the currently-transmitted data frame, and then revert back to the standard communication mode. In other embodiments, the secondary device 450 may remain in this receiving mode of operation for a predetermined time period or until suitable conditions have been met, and then revert back to the standard communication mode. To provide some illustrative examples, the secondary device 450 may remain in the receiving mode after its initial transition until expiration of a predetermined threshold time period. As another illustrative example, the secondary device 450 may be instructed to toggle between the transmitting mode and the receiving mode in response to device-specific alternative communication mode commands that are received, such as the use of the encoded transmit and receive addresses as noted herein.

Again, in each of the embodiments as discussed herein, different schemes are used to define the use of an alternative communication mode command. As noted herein, the command is recognized by the secondary device 450 in accordance with a predetermined modification that may deviate from the SPC protocol, and which causes the secondary device 450 to transition from the standard communication mode (which may be referred to as a transmitting mode of operation with respect to the secondary device 450) to the alternative communication mode (which may be referred to as a receiving mode of operation with respect to the secondary device 450). Thus, and as noted above, the communication circuitry 456 is configured to receive the trigger signal that is transmitted to the communication path. The trigger signal may comprise any of those as discussed above, which again functions as the alternative communication mode command.

The processing circuitry 452 may then measure any suitable number of parameters of the trigger signal, which may include for instance the length, amplitude, shape, and/or polarity of the trigger signal or any portions thereof as noted herein (e.g. the dual consecutive short trigger pulses). The secondary device 450 may be configured to recognize the trigger signal as the alternative communication mode command when the processing circuitry 452 determines that one or more of these measured parameters match a predetermined set of parameters that are associated with the alternative communication mode command. As an illustrative example, the processing circuitry 452 may, in response to a measured length of time of the trigger signal corresponding to an encoded alternative communication mode command, transition the secondary device 450 to a receiving mode of operation. Upon doing so, the communication circuitry 456 may then receive data encoded in the data bit groups that are transmitted by the primary device 400 in accordance with the SPC protocol, as noted herein. The secondary device 450 may implement this functionality by, for example, updating the program memory 470 in accordance with the particular scheme that is implemented, with the processing circuitry 452 executing the instructions associated with the program memory 470 to determine whether the alternative communication mode command has been received. In this way, a sensor that operates in accordance with the standard communication mode may be upgraded to operate in accordance with the alternative communication mode as discussed herein by updating the program memory 470 for instance.

Section II: An SPC trigger pulse with increased resolution and reference time base delivery

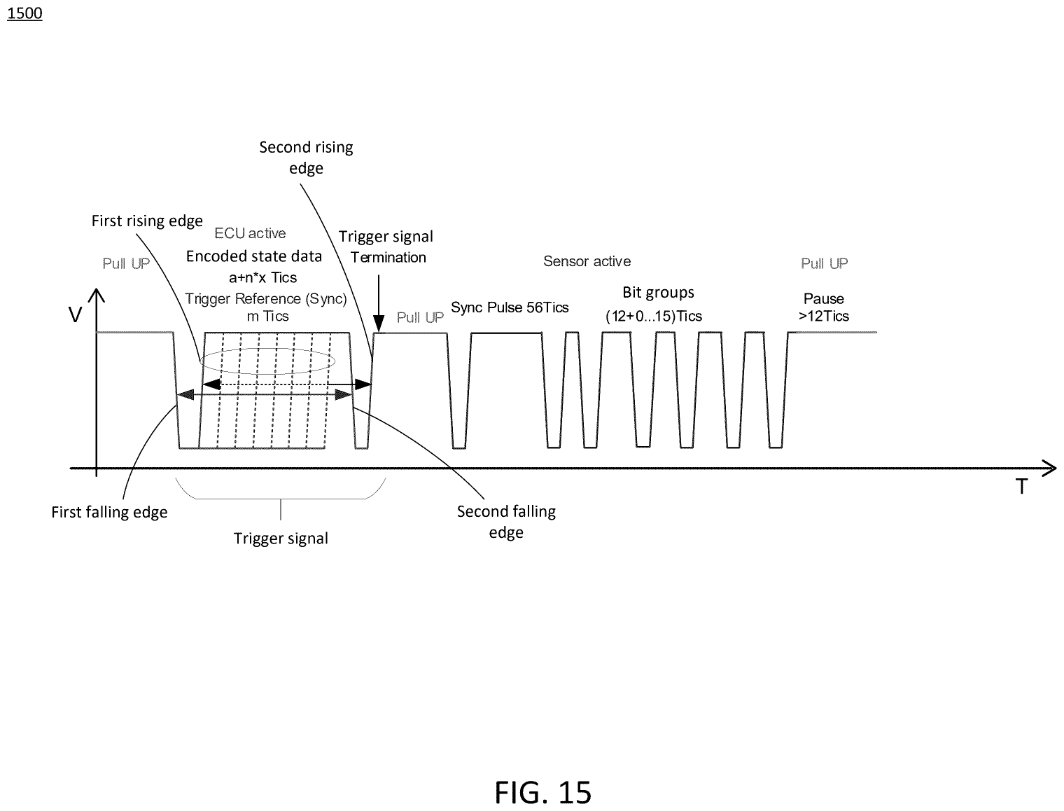

FIGS. 15, 16A-16B, and 17-19 illustrate example signaling schemes implemented by a device and a corresponding time-varying state of a data line to implement an SPC trigger pulse with increased resolution and reference time delivery, in accordance with one or more embodiments of the disclosure. These signaling schemes may be used, for example, to replace the trigger pulse that is transmitted in accordance with the standard SPC communication protocol as shown in FIG. 1, for instance, with a trigger signal.

Referring first to FIG. 15, the communication circuitry 406 is configured to transmit a trigger signal over the communication path by way of the modulation of the DATA line as shown, which functions to initiate communication with the secondary device 450 in accordance with the SPC communication protocol. The trigger signal encodes state data with respect to the secondary device 450 as well as a time base reference of the primary device 400. Again, the trigger signal as shown in FIG. 15 may replace the transmission of the trigger pulse that is typically transmitted in accordance standard SPC communication protocol as shown in FIG. 1 for instance.

However, and as discussed in further detail below, the trigger signal may have a shape that differs from the standard SPC trigger pulse. For instance, and as further discussed below with respect to each of FIGS. 15, 16A-16B, and 17-19, the trigger signal may have any suitable number of edges, each having a respective direction. That is, and as discussed in further detail below, the trigger signal may include one or more rising edges and one or more falling edges. The rising edges may be identified as having one direction, e.g. a slope having a temporal direction that defines such edges as transitioning from a lower to a higher voltage value. Each of the rising edges of the trigger signal may be considered as having the same direction as one another, excepting for driver and/or timing tolerances. The falling edges may be identified as having another, different direction, e.g. a slope having a temporal direction that defines such edges as transitioning from a higher to a lower voltage value. Each of the falling edges of the trigger signal may also be considered as having the same direction as one another, excepting for driver and/or timing tolerances. Thus, the rising and falling edges may alternatively be described herein as edges having a specific direction, with the rising edges having the same direction as one another and the falling edges having another, different direction that is the same as one another, but is different than the direction of the rising edges.

For example, the trigger signal as shown in FIG. 15 includes four edges, which as shown includes two rising edges and two falling edges. That is, the trigger signal has a shape that begins with a first (fixed) falling edge, transitions to a first (variable) rising edge, transitions to a second (fixed) falling edge, and finally transitions to a second (fixed) rising edge, which represents the entirety of the trigger signal as shown in FIG. 15. Thus, for the example shown in FIG. 15, the overall duration of the trigger signal may be fixed per transmission (e.g. from the first falling edge to the second rising edge), and may exceed the maximum trigger pulse length defined in accordance with the SENT and/or SPC communication protocols (e.g. 65 tics or an upper range of this encoded bus code). Moreover, the duration of time between the first and the second falling edge is likewise fixed in duration, and functions to encode the time base reference of the primary device 400, as discussed in further detail below.

However, the duration of time between the two rising edges, which is used to encode the state data, may be a variable duration that is a function of the specific state data that is intended to be conveyed to the secondary device 450. Thus, the state data may be encoded in a similar manner as the use of the different bus codes, i.e. via the different PWM-encoded time lengths of 11, 21, 38, or 65 tics used in the standard SPC communication protocol, as discussed above with respect to FIG. 1. Thus, the state data may be encoded in the trigger signal as one of several different PWM time-encoded values represented as different predetermined lengths of time, each representing a different state to be transmitted to the secondary device 450.

The state data that is encoded in this manner may represent any suitable information that is to be transmitted to the secondary device 450. That is, and as noted above with respect to the use of the transmitted data bit groups, the encoded state data may define a bit value based upon the number of states that are in an overall set of state data for a particular application. Thus, the state data may represent an encoded number that is based upon the number of bits that may be encoded per state. As an illustrative example, the number of states may include 8 states, which may encode up to 8 different three bit values, 16 states, which may encode up to 16 different four bit values, etc. Thus, the state data may be encoded using a PWM encoding scheme by varying a temporal position between two of the four edges of the trigger signal as discussed herein, such that each state represents a different encoded value in terms of a number of bits that is a function of the number of overall set of state data that may be encoded.

For instance, the state data may represent a sensor address that is used by each receiving sensor to determine whether sensor data is being requested from that particular sensor, as noted above. Additionally or alternatively, the state data may represent a value representing bit values that define sensor configuration data to instruct a sensor with respect to the manner of its operation, how sensor measurements are to be performed, a frequency of transmission, etc. The state data is not limited to such examples, and may represent any suitable instruction, command, etc., which is recognized by the secondary device 450 and, in response, causes a predetermined response by the secondary device 450. In any event, the processing circuitry 402 is configured to first generate the state data based upon the particular instruction, command, data, etc., that is to be conveyed to the secondary device 450. This may include, for instance, the processing circuitry requesting sensor data, determining that a sensor needs a specific configuration during startup, etc.

As additional examples, the state data as discussed in this Section that may be encoded as part of the trigger signal may include a command instructing the secondary device 450 to enter into a receiving mode of operation or to return to a standard transmitting mode of operation. For example, one of the encoded states of the trigger signal as discussed in further detail in this Section may be used as the alternative communication mode command as discussed above in Section I. As yet another example, another one of the encoded states of the trigger signal as discussed in further detail in this Section may be used as a command to instruct the secondary device 450 to remain in a receiving mode of operation, to return to the standard transmitting mode of operation, etc. As yet additional examples, the encoded states of the trigger signal as discussed in further detail in this Section may be used on a per secondary device basis such that a state is correlated with a specific command that is recognized by specific secondary devices but ignored by others. In this way, the use of the higher resolution trigger signal that is discussed in this Section may be used to support a larger number of secondary devices, with each device being assigned its own receive mode command and/or transmit mode command.

Moreover, and in contrast with the conventional SPC communication protocol trigger pulse, the trigger signal also encodes the time base reference of the primary device 400. To do so, the processing circuitry 402 is configured to generate (e.g. calculate) the time base reference for the primary device 400 based upon a clock frequency of the primary device 400, which is typically a more accurate clock compared to that of the secondary device 450. The processing circuitry 402 may generate the time base reference in terms of any suitable number ‘m’ of unit time values, or tics, as shown in FIG. 15. This may be performed, for example, in the same manner as the secondary device 450 when transmitting the sync pulse in accordance with the SPC communication protocol.

For example, the processing circuitry 402 may calculate a tic value as a proportion of and/or with reference to a clock frequency that is used for communications. As an illustrative example, the processing circuitry 402 may calculate the tic value in terms of a time of one or more clock cycles of the clock frequency. The time base reference may thus be expressed as a single tic value, and the processing circuitry 402 may encode the time base reference of the primary device 400 in terms of duration of time that is a predetermined multiple of these tic values. For example, like the use of the 56 tics for the standard SPC communication protocol, the number ‘m’ of tics used to encode the time base reference of the primary device 400 may also be fixed and known (e.g. pre-programmed into) the primary and secondary devices 400, 450.

Thus, the trigger signal encodes the time base reference of the primary device 400 and the state data by modulating the DATA line to have a specific shape over time. Thus, the time base reference of the primary device 400 data may also be encoded using a PWM encoding scheme by varying a temporal position between two of the four edges of the trigger signal as discussed herein. Again, in the present example, the durations of time between the falling and rising edges function to encode the time base reference of the primary device 400 and the state data for the secondary device 450, respectively. Again, this encoding may be achieved, for example, via the communication circuitry 406 modulating the state of the DATA line between the higher and the lower voltage values as shown in FIG. 15.

The encoding of the time base reference of the primary device 400 in this manner enables the secondary device 450 to decode the encoded state data using the higher accuracy clock of the primary device 400 as a time base reference. For example, the secondary device 450 may use the encoded time base reference to measure the time between the two rising edges relative to the reference time between the two falling edges to derive the encoded state data based upon the more accurate clock of the primary device 400. As an illustrative example, the secondary device 450 may be configured to recognize (e.g. via pre-programming) that the encoded time base reference of the primary device 400 has a duration of 50 tics in terms of the time base reference of the primary device 400. Thus, if the duration of time between the two falling edges of the trigger signal measures 100 microseconds, then the secondary device 450 may identify the time base reference of the primary device 400 as 1 tic=2 microseconds. The secondary device 400 may then measure the time between the two rising edges of the trigger signal, which again encodes the state data, to decode the state data in terms of the time base reference of the primary device 400 that was derived from the encoded time base reference in the trigger signal. For instance, and continuing this example, if the time between the two rising edges of the trigger signal is measured as 16 microseconds, then the secondary device 450 may determine that the encoded state data represents 8 tics in length, and correlate the 8 tic value to a predetermined instruction, command, state, address, etc., based upon the particular application.

Thus, the reliance on the more accurate clock of the primary device 400 in this manner facilitates the use of a higher granularity trigger pulse, which allows for the state data to be encoded using a smaller number of tics than that defined in accordance with the conventional SPC communication protocol. Additionally, the separation between the different predetermined lengths used to define different states may also be reduced, as the typical 20% clock tolerance of the secondary device clock is no longer used as a time base reference, as the more accurate clock of the primary device 400 now defines the time base reference of the primary device 400 that is used by the secondary device 450. For example, and as shown in FIG. 15, the state data may be encoded using a first rising edge that is offset a duration ‘a’ from the first falling edge of the trigger signal. Again, the temporal position of the second rising edge is fixed irrespective of the sensor state data that is encoded in the trigger signal. Thus, the sensor state data may encode any suitable number of ‘n’ states by varying the position of the first rising edge with respect to the second rising edge. That is, the communication circuitry 406 may be configured to modulate the DATA line to vary a temporal position of the first rising edge by a predetermined time period with respect to the second rising edge to encode each one of a set of state data. Each state (in the set of state data) is thus encoded as a predetermined duration of time from the second rising edge, and is represented in terms of ‘x’ tics with respect to the primary device 400 time base. In other words, the variable first rising edge may be temporally shifted within the trigger signal by a+(n*x) tic values depending upon the particular state to be encoded, with x tics representing the duration of each time-encoded state n.

In this way, each of the n states may be encoded via a smaller number of tic values (x) than those implemented for a conventional SPC communication protocol trigger pulse, given the use of the higher accuracy clock of the primary device 400 as the time base reference. Therefore, the trigger signal may encode additional states compared to the conventional SPC communication protocol trigger pulse for a trigger signal having the same duration, i.e. more states may be transmitted with a single trigger signal having the same duration as a standard SPC trigger pulse. As an additional benefit, the trigger signal may alternatively be reduced in length to encode the same (or even more) states as the conventional SPC communication protocol trigger pulse, thereby facilitating a shorter trigger signal length for the same amount (or even more) different states that may be transmitted. As yet another added benefit of this signaling scheme, in the example shown in FIG. 15, the measurement via the secondary device 450 of the encoded state data and the encoded time base reference of the primary device 400 are respectively performed between equal direction edges. Thus, inaccuracies due to different driver capability on the high and low voltage sides are removed, in contrast with the conventional SPC communication protocol trigger pulse that is measured from the first falling edge to the next rising edge.

Again, in the example shown in FIG. 15, the trigger signal may replace the use of the conventional SPC trigger pulse to deliver the time base reference of the primary device 400 and state data to the secondary device 450. In the present embodiments, the secondary device 450 may receive the trigger signal, decode the state data as noted above, but otherwise not utilize the encoded time base reference to calibrate its own clock. Thus, other than the initial transmission of the trigger signal as shown in FIG. 15, the primary device 400 and the secondary device 450 may then communicate with one another in the same manner as defined in accordance with the conventional SPC communication protocol.

For instance, the secondary device 450 may respond to the received trigger signal by transmitting the sync pulse as shown, which includes the time base reference of the secondary device 450. The primary device 400 may then use the sync pulse, which again has a predetermined duration of 56 tics as shown, to calibrate its own reference clock frequency to match that of the secondary device 450, as discussed above. That is, the sync pulse has a defined length in terms of the secondary device 450 time base, which is referenced from the secondary device 450 clock frequency, is expressed as a length of 56 tics, and is received by the primary device 400. The primary device 400 measures the length of the 56 tic sync pulse to derive the time base of the secondary device 450 and then calibrate the time base of the primary device 400 to match that of the secondary device 450. For example, the primary device 400 may measure the length of the sync pulse and determine that the 56 tics used by the secondary device 450 are 10% higher, 5 % lower, etc., than that of the clock implemented by the primary device 400 used to define the time base of the primary device 400. Thus, upon calibrating the time base reference at the primary device 400, the primary device 400 may adjust its clock frequency to ensure that the time base of the primary and the secondary devices 400, 450 are synchronized with one another (e.g. the tic values match) despite deviations between the clocks used at each device.

The secondary device 450 may then, in response to receiving the trigger signal, also transmit data (e.g. sensor data) to the primary device 400, which may occur in accordance with the conventional SPC communication protocol for instance. For example, this may include the secondary device 450 transmitting the bit groups as shown, which may encode any suitable data using a timing and voltage that complies with the conventional SPC communication protocol. In this example, the PWM encoding of the data bit groups in this manner utilizes the time base of the secondary device 450. The data bit groups may represent four or less bits based upon the particular application. For instance, each of the data bit groups may encode four bits, and in such a case be referred to as data nibbles. However, for other applications, a reduced number of bits may be encoded per PWM cycle. In accordance with such applications, the data bit groups may encode less than four bits, such as three bits for instance.

In any event, the time between two consecutive falling edges of each transmitted data bit group may define an N-bit value (with N being 4 or less), and thus may represent an encoded number between 0 and 15 when four bits are encoded, between 0 and 7 when 3 bits are encoded, etc. The transmission time (i.e. the time during which the data line remains low) for each data bit group therefore depends on the transmitted encoded data values. All values are multiples of the UT (i.e. tic) value, which again is known by the primary and secondary devices 400, 450 via the use of the time base reference synchronization processes as discussed in further detail herein (which may be performed via either of the primary or the secondary devices 400 450, in various embodiments).

Again, in the present embodiment, the primary device 400 may calibrate its clock frequency as noted above to match that of the secondary device 450, and then use this calibrated clock frequency to receive and decode the data that is encoded in the transmitted bit groups. This time base synchronization process is described above with respect to the primary device 400, which is part of the conventional SPC communication protocol and is generally known. However, in the embodiments described in further detail below, the clock calibration process may alternatively be performed via the secondary device 450 using the time base reference encoded in the trigger signal transmitted by the primary device 400. That is, the time base reference encoded as part of the trigger signal as discussed above with respect to FIG. 15 enables the secondary device 450 to calibrate its own clock frequency in the same manner that is typically performed by the primary device 400 in accordance with the conventional SPC protocol.

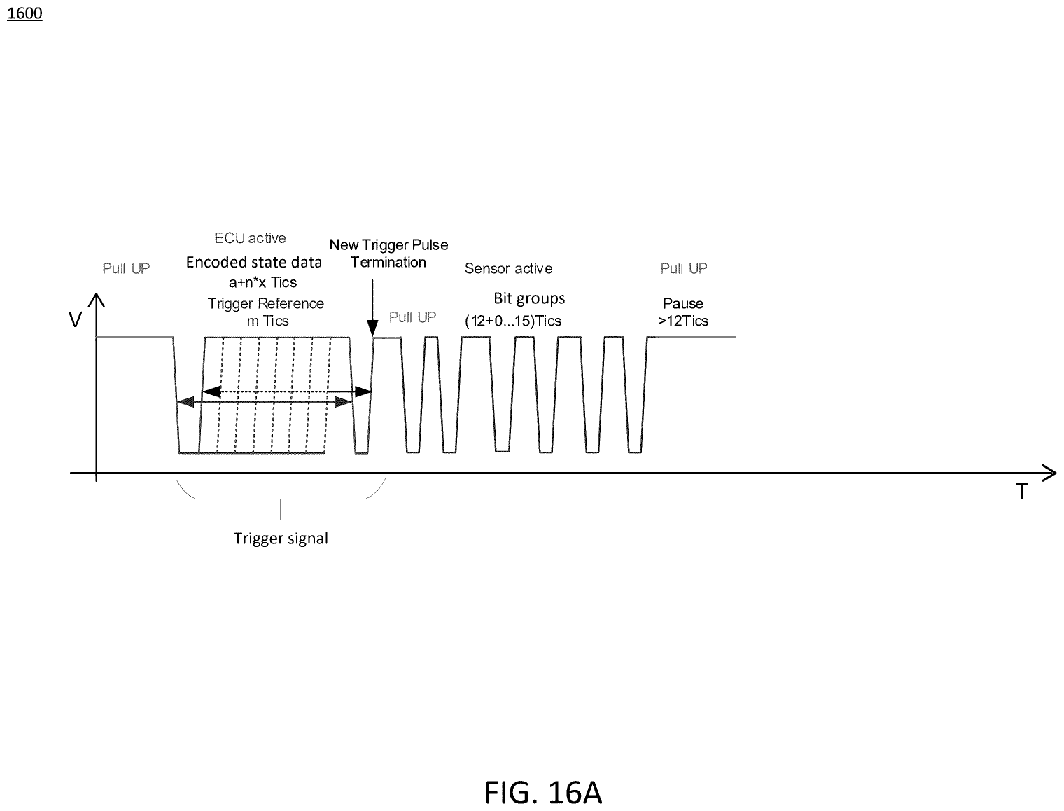

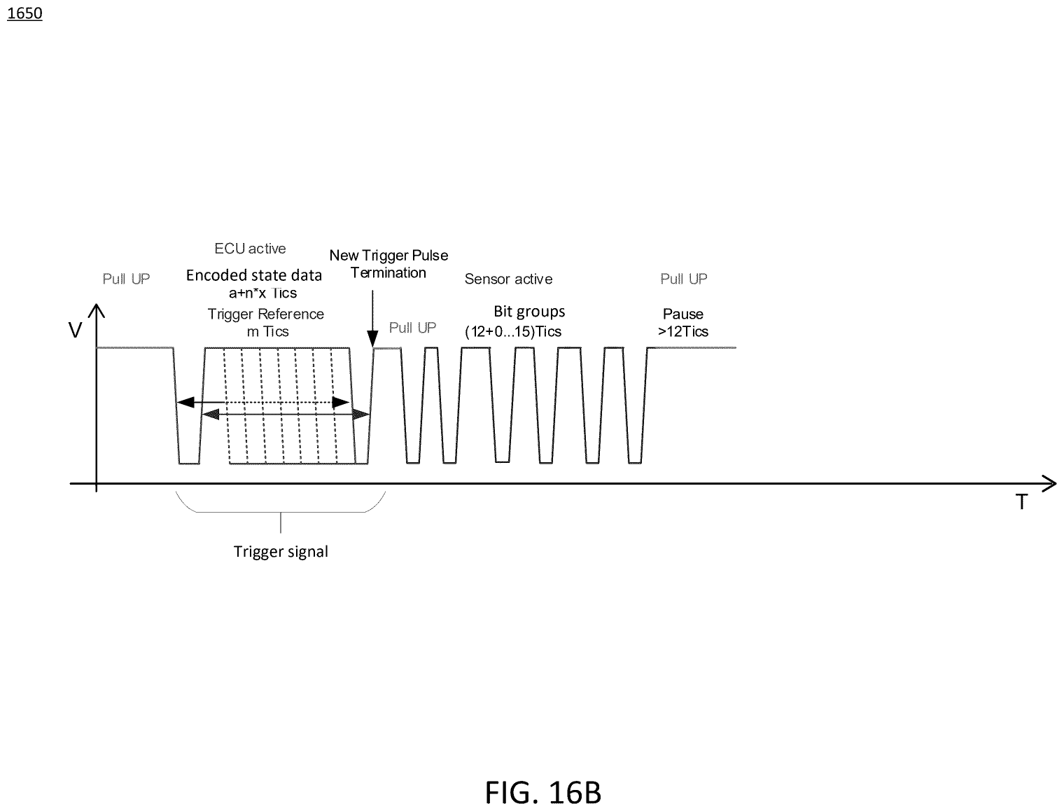

As a result, when the secondary device 450 calibrates its own clock frequency in this manner, the secondary device 450 need not transmit a sync pulse to the primary device 400, as shown in the signaling scheme illustrated in FIGS. 16A-16B. For example, FIG. 16A illustrates the same signaling scheme as shown in FIG. 15, except that in this scenario the primary device 400 receives the data encoded in the bit groups transmitted from the secondary device 450 without receiving any synchronization signal (e.g. a sync pulse used in accordance with the conventional SPC communication protocol from the secondary device 450).

Thus, in accordance with such embodiments, the secondary device 450 may encode the data in the transmitted data bit groups in terms of the time base of the primary device 400 instead of its own time base, as is the case for the conventional SPC communication protocol. The primary device 400 may then decode the transmitted data bit groups using its own time base without the need for clock calibration. This obviates the need for the secondary device 350 to transmit the sync pulse, advantageously reducing the latency of communications between the primary and secondary devices 400, 450.

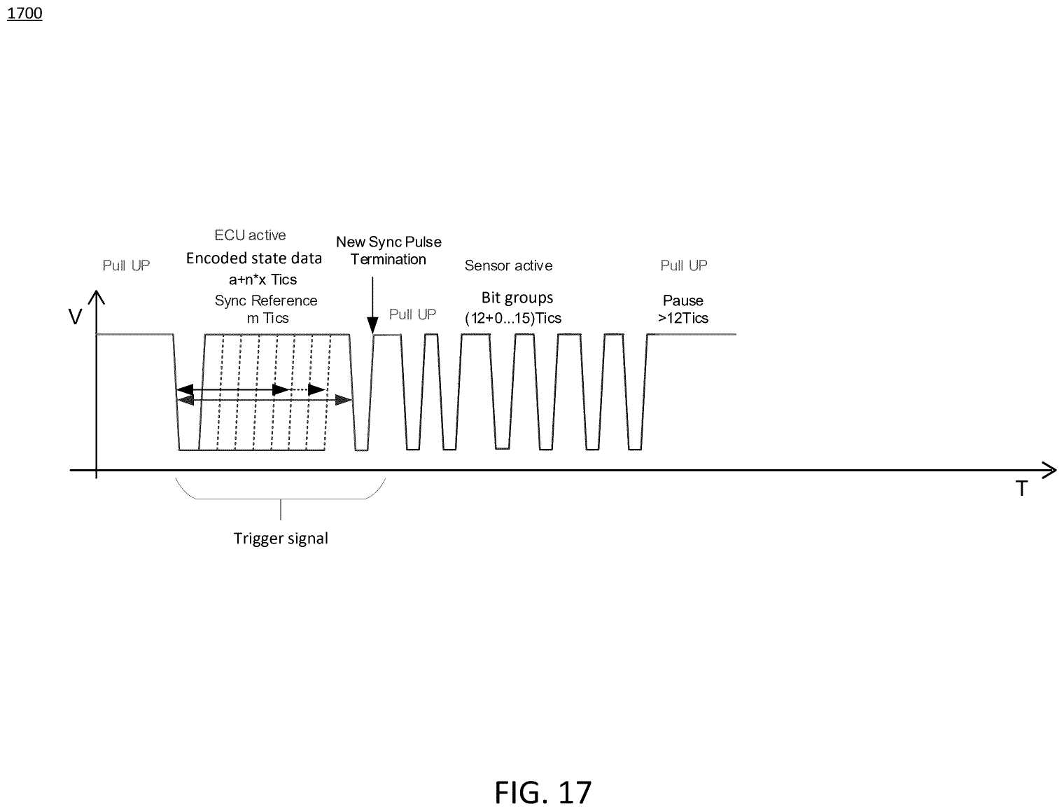

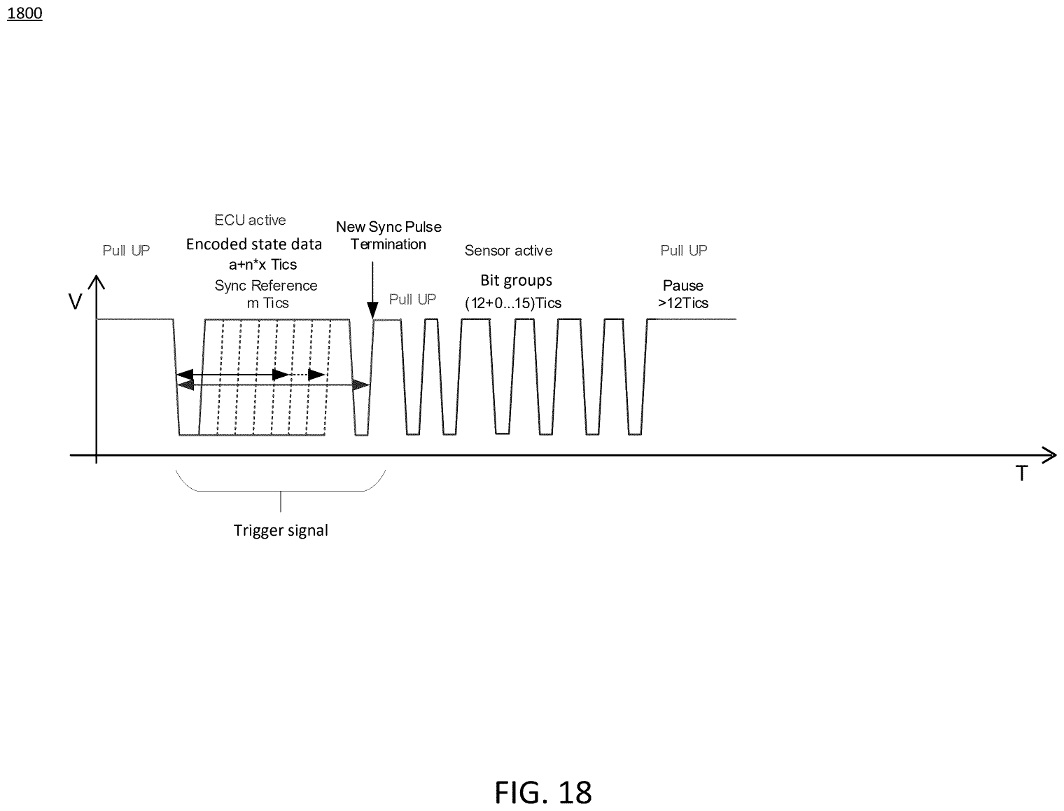

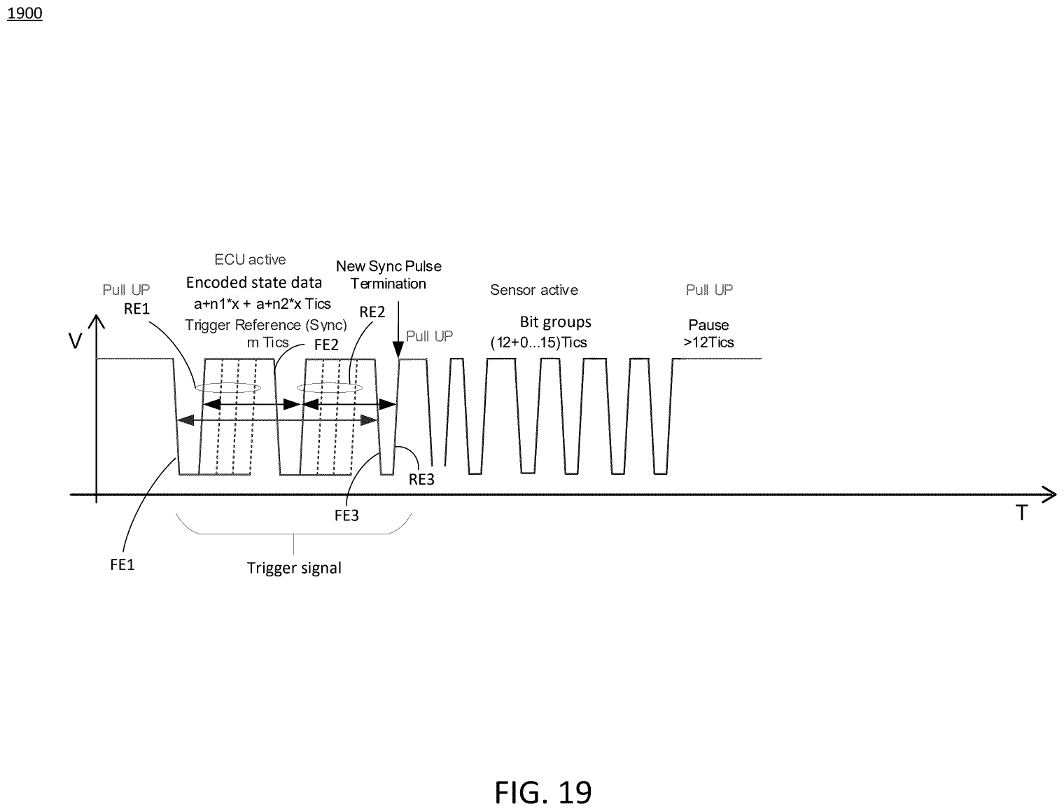

The manner in which the time base reference of the primary device 400 and the state data are encoded in the trigger signal is shown in FIGS. 15 and 16A, which represents one such example. FIGS. 16B, 17, and 18 illustrate alternative examples of how the trigger signal may encode the time base reference of the primary device 400 and the state data. For each of the trigger signals as shown in FIGS. 17 and 18, the trigger signal may have the same shape as that of the trigger signal shown in FIGS. 15 and 16A above, and in each case also be received, decoded, and used by the secondary device 450 in the same manner as discussed above with respect to FIGS. 15 and 16A. However, and as described in further detail below, the trigger signal as shown in FIGS. 16B and 19, the trigger signal may have a different shape as that of the trigger signal shown in FIGS. 15 and 16A above, although in each case the trigger signal may also be received, decoded, and used by the secondary device 450 in the same manner as discussed above with respect to FIGS. 15 and 16A.

Additionally, although FIGS. 16B and 17-19 illustrate a signaling scheme that does not include the transmission of a sync pulse via the secondary device 450, as was discussed with respect to FIG. 16A, this is by way of example and not limitation. In other embodiments, the signaling schemes as shown in FIGS. 16B and 17-19 may include the secondary device 450 transmitting the sync pulse as shown in FIG. 15, which may be used by the primary device 400 to adapt its clock frequency as discussed above.

FIG. 16B illustrates a trigger signal that may be a different shape as that shown in FIG. 16A, and in this case also includes four edges, which includes a first falling edge followed by a first rising edge, a second falling edge, and a second rising edge. The time base reference of the primary device 400 is encoded in the trigger signal as shown in FIG. 16B between two edges having the same direction, as was the case in FIG. 16A. However, for the trigger signal as shown in FIG. 16B, the time base reference of the primary device 400 is encoded in the trigger signal by way of the duration of time measured between the first and the second rising edges instead of the first and second falling edges as discussed above with respect to FIGS. 15 and 16A. Additionally, for the trigger signal in FIG. 16B, the state data is also encoded as a duration of time between two edges having the same direction, as was the case in FIG. 16A. However, instead of being encoded by way of the duration of time measured from the first falling edge to the first rising edge, the state data of the trigger signal as shown in FIG. 16B encodes the state data as a time measured from the first falling edge to the second falling edge. In other words, for the encoding of the state data for the trigger signal as shown in FIG. 16B, the state data is encoded by way of a variable temporal position of the second falling edge with respect to a fixed temporal position of the first falling edge based upon the state data to be encoded.

FIG. 17 illustrates a trigger signal that may be the same shape as that shown in FIGS. 15 and 16A, and thus also includes a first falling edge followed by a first rising edge, a second falling edge, and second rising edge. The time base reference of the primary device 400 is also encoded in the trigger signal as shown in FIG. 17 by way of the duration of time measured between the first and the second falling edges, as discussed above with respect to FIGS. 15 and 16A. However, for the trigger signal in FIG. 17, the state data is instead encoded by way of the duration of time measured from the first falling edge to the first rising edge, which also has a variable temporal position in this example based upon the state data to be encoded.

In this example, the communication circuitry 406 may be configured to modulate the DATA line to vary a temporal position of the first rising edge by a predetermined time period with respect to the first falling edge to encode each one of a set of state data. As noted above, each state (in the set of state data) is thus encoded as a predetermined duration of time, but in this example is measured from the first falling edge of the trigger signal, and is represented in terms of ‘x’ tics with respect to the primary device 400 time base. As was the case for the trigger signal encoding as discussed above with respect to FIGS. 15 and 16A-16B, the variable first rising edge may be temporally shifted within the trigger signal by a+(n*x) tic values depending upon the particular state to be encoded, with x tics representing the duration of each time-encoded state n.

FIG. 18 illustrates a trigger signal that may have the same shape as that shown in FIGS. 15 and 16A, and thus also includes a first falling edge followed by a first rising edge, a second falling edge, and second rising edge. As was the case for the encoding described with respect to FIG. 17, the trigger signal as shown in FIG. 18 also encodes each state (in the set of state data) as a predetermined duration of time measured from the first falling edge, which again is represented in terms of ‘x’ tics with respect to the primary device 400 time base. However, the trigger signal as shown in FIG. 18 alternatively encodes the time base reference of the primary device 400 by way of the duration of time measured between the first falling edge and the second rising edge.

Turning now to FIG. 19, an alternative trigger signal is shown that has a different shape than those discussed above with respect to FIGS. 15-18, and also encodes the state data and the time base reference of the primary device 400 in a different way. For instance, the trigger signal as shown in FIG. 19 includes two separate pulses, and thus comprises six edges, which include the three rising edges RE1, RE2, RE3, as well as three falling edges FE1, FE2, FE3 as shown. The trigger signal starts with the first falling edge FE1 and terminates with the third rising edge RE3. Although two different pulses are shown, this is by way of example and not limitation, and the trigger signal may include any suitable number of separate pulses, with the overall length of the trigger signal thus having a duration between the first falling edge and the last rising edge in each case.

The trigger signal as shown in FIG. 19 may still encode the time base reference of the primary device 400, which in this example may be encoded by way of the length of time measured between the first and last falling edges FE1, FE3. And, as was the case for the encoding schemes described above with respect to FIGS. 15, 16A, and 16B, each of the rising and falling edges of the trigger signal have a temporal position that is fixed with respect to one another per trigger signal transmission with the exception of, in this example, the first and second rising edges RE1, RE2, which are used to encode the state data.

Thus, the use of additional pulses in this example enables the trigger signal to encode additional state data per single transmission (e.g. one per pulse) while still providing the time base reference of the primary device 400. By encoding different state data in this manner, the trigger pulse may convey multiple states, which may comprise separate instructions, commands, etc., or a portion of a larger encoded value representing a command, instruction, etc. As an illustrative example, the first state data may encode the MSBs of a larger encoded value, whereas the second state data may encode the LSBs of this larger encoded value, or vice-versa.

In the example as shown in FIG. 19, first state data is encoded in the trigger signal as a predetermined length of time between the first and the second rising edge RE1, RE2, and second sensor state data is encoded in the trigger signal as a length of time between the second and the third rising edges RE2, RE3. Thus, although the first and second rising edges are variable and may change based upon the state data to be encoded, each is still referenced to the fixed third rising edge RE3. Thus, the secondary device 450 may measure the time between the second rising edge RE2 and the third rising edge RE3 to decode the second state data, and also measure the additional time from the second rising edge RE2 to the first rising edge RE1 to decode the first state data.

The specific edges used to encode the state data in this manner are illustrated in FIG. 19 by way of example and not limitation, and any other edges may be used to encode the state data and/or the time base reference of the primary device 400. For example, the first and the second state data may be encoded as a length of time measured from the first falling edge FE1, as discussed above with respect to FIGS. 17 and 18. Alternatively, the first state data may be encoded as a length of time measured from the first falling edge FE1, whereas the second state data may be encoded as a length of time measured from the third rising edge RE3. Thus, any suitable combination of the falling and rising edges of the trigger signal may be used to encode the state data as well as the time base reference of the primary device 400. As another example, the time base reference of the primary device 400 may be encoded as a length of time measured between the first falling edge FE1 and the third rising edge RE3, as was the case for the trigger signal encoding discussed with respect to FIG. 18.

It is noted that the polarity and/or timing of the pulses of the trigger signal may be constructed in a manner that allows the receiving secondary device 450 to differentiate the trigger signal from other data bit group transmissions. For instance, multiple secondary devices may transmit data on the same bus to the primary device 400, and thus these data bit groups may be received by the other secondary devices. Thus, the trigger signal may be constructed such that a secondary device 450 receiving data bit group transmissions from other secondary devices does not interpret these transmissions as a trigger signal. For example, to prevent this, the trigger pulses of the trigger signal may have length that violates the maximum duration of 27 tics per bit groups duration as defined in accordance with the conventional SPC communication protocol.

### EXAMPLES

The techniques of this disclosure may also be described in the following examples.

Example 1. A device configured to communicate with a sensor via a communication path, the device comprising: processing circuitry configured to generate a data frame; and communication circuitry configured to transmit the data frame over the communication path, the data frame comprising a trigger signal and a plurality of data bit groups, wherein the plurality of data bit groups are transmitted in accordance with a pulse width modulation (PWM) code protocol, and wherein the trigger signal indicates to the sensor to transition from a transmitting mode of operation to a receiving mode of operation to receive data encoded in the plurality of data bit groups.

Example 2. The device of Example 1, wherein the trigger signal occurs for a length of time that indicates to the sensor to transition from the transmitting mode of operation to the receiving mode of operation, and wherein the length of time of the trigger signal is from among a plurality of predetermined lengths of time, with other ones of the plurality of predetermined lengths of time representing respective encoded sensor addresses or respective sensor configuration data.

Example 3. The device of any combination of Examples 1-2, wherein the length of time of the trigger signal that indicates to the sensor to transition from the transmitting mode of operation to the receiving mode of operation is greater than the other ones of the plurality of predetermined lengths of time.

Example 4. The device of any combination of Examples 1-3, wherein at least a portion of the plurality of data bit groups comprise encoded data indicative of an address of the sensor.

Example 5. The device of any combination of Examples 1-4, wherein: the processing circuitry is configured to generate a time base reference for the device that is based upon a device clock frequency, the trigger signal comprises at least four edges including two edges having a first direction and two edges having a second direction that is different than the first direction, the time base reference of the device is encoded in the trigger signal as a length of time between two of the at least four edges having the same direction, and the time base reference enables the sensor to calibrate a sensor clock frequency to decode data encoded in the plurality of data bit groups.

Example 6. The device of any combination of Examples 1-5, wherein the trigger signal comprises two consecutive pulses.

Example 7. The device of any combination of Examples 1-6, wherein the trigger signal comprises a further pulse that precedes the two consecutive pulses, and wherein the further pulse has a length of time that represents an encoded address of the sensor or sensor configuration data.

Example 8. The device of any combination of Examples 1-7, wherein the trigger signal comprises two consecutive pulses, and wherein a length of time of each of the two consecutive pulses is less than a minimum length of time of a trigger pulse defined in accordance with the PWM code protocol and indicates to the sensor to transition from the transmitting mode of operation to the receiving mode of operation.

Example 9. The device of any combination of Examples 1-8, wherein the trigger signal comprises two consecutive pulses, and wherein the length of time of each of the two consecutive pulses is less than other ones of the plurality of predetermined lengths of time and indicates to the sensor to transition from the transmitting mode of operation to the receiving mode of operation.

Example 10. The device of any combination of Examples 1-9, wherein the data frame does not include a synchronization pulse.

Example 11. The device of any combination of Examples 1-10, wherein the communication circuitry is configured to: transmit the trigger signal; receive, from the sensor, a sensor time base reference that is based upon a sensor clock frequency; and transmit the plurality of data bit groups to the sensor that are encoded based upon the sensor time base reference.

Example 12. The device of any combination of Examples 1-11, wherein the sensor is from among a plurality of sensors configured to receive the trigger signal, and wherein the trigger signal (i) indicates to each one of the plurality of sensors to transition from a transmitting mode of operation to a receiving mode of operation, or (ii) indicates to only the sensor to transition from the transmitting mode of operation to the receiving mode of operation.

Example 13. A sensor configured to communicate with a device via a communication path, the sensor comprising: communication circuitry configured to receive a trigger signal that is transmitted to the communication path; and processing circuitry configured to, in response to a measured length of time of the trigger signal corresponding to an encoded receive mode command, transition the sensor to a receiving mode of operation, wherein the communication circuitry is configured, upon the sensor transitioning to the receiving mode of operation, to receive data encoded in a plurality of data bit groups that are transmitted to the communication path in accordance with a pulse width modulation (PWM) code protocol.

Example 14. The sensor of Example 13, wherein the measured length of time of the trigger signal corresponding to the encoded receive mode command is from among a plurality of predetermined lengths of time, with other ones of the plurality of predetermined lengths of time representing respective encoded sensor addresses or respective sensor configuration data.

Example 15. The sensor of any combination of Examples 13-14, wherein the measured length of time of the trigger signal corresponding to the encoded receive mode command is greater than the other ones of the plurality of predetermined lengths of time.

Example 16. The sensor of any combination of Examples 13-15, wherein at least a portion of the plurality of data bit groups comprise encoded data indicative of an address of the sensor.

Example 17. The sensor of any combination of Examples 13-16, wherein the trigger signal corresponding to the encoded receive mode command comprises at least four edges including two edges having a first direction and two edges having a second direction that is different than the first direction, and wherein the measured length of time of the trigger signal corresponding to the encoded receive mode command comprises a time period between one of the four edges having the first direction and another one of the four edges having the second direction.

Example 18. The sensor of any combination of Examples 13-17, wherein a time base reference of the device that is based upon a device clock frequency is encoded in the encoded receive mode command as a length of time between two of the at least four edges having the same direction, and wherein the processing circuitry is configured to use the time base reference of the device to calibrate a sensor clock frequency to decode the data encoded in the plurality of data bit groups.

Example 19. The sensor of any combination of Examples 13-18, wherein the trigger signal corresponding to the encoded receive mode command comprises two consecutive pulses.

Example 20. The sensor of any combination of Examples 13-19, wherein the trigger signal corresponding to the encoded receive mode command comprises a further pulse that precedes the two consecutive pulses, and wherein the further pulse has a length of time that represents an encoded address of the sensor.

Example 21. The sensor of any combination of Examples 13-20, wherein the trigger signal corresponding to the encoded receive mode command comprises two consecutive pulses, and wherein the measured length of time of the two consecutive pulses is less than a minimum length of time of a trigger pulse defined in accordance with the PWM code protocol and indicates to the sensor to transition to the receiving mode of operation.

Example 22. The sensor of any combination of Examples 13-21, wherein the trigger signal corresponding to the encoded receive mode command comprises two consecutive pulses, and wherein the measured length of time of each of the two consecutive pulses is less than other ones of the plurality of predetermined lengths of time and indicates to the sensor to transition to the receiving mode of operation.

Example 23. The sensor of any combination of Examples 13-22, wherein the communication circuitry is configured to transmit, in accordance with the PWM code protocol, a sensor time base reference to the device that is based upon a sensor clock frequency, and wherein the plurality of data bit groups are encoded based upon the sensor time base reference.

### CONCLUSION

Although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

It is further to be noted that specific terms used in the description and claims may be interpreted in a very broad sense. For example, the terms “circuit” or “circuitry” used herein are to be interpreted in a sense not only including hardware but also software, firmware or any combinations thereof. The term “data” may be interpreted to include any form of representation data. The term “information” may in addition to any form of digital information also include other forms of representing information. The term “entity” or “unit” may in embodiments include any device, apparatus circuits, hardware, software, firmware, chips, or other semiconductors as well as logical units or physical implementations of protocol layers etc. Furthermore, the terms “coupled” or “connected” may be interpreted in a broad sense not only covering direct but also indirect coupling.

It is further to be noted that methods disclosed in the specification or in the claims may be implemented by a device having means for performing each of the respective steps of these methods.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This disclosure is intended to cover any adaptations or variations of the specific embodiments discussed herein.

1. A device configured to communicate with a sensor via a communication path, the device comprising:
processing circuitry configured to generate a data frame; and
communication circuitry configured to transmit the data frame over the communication path, the data frame comprising a trigger signal and a plurality of data bit groups,
wherein the plurality of data bit groups are transmitted in accordance with a pulse width modulation (PWM) code protocol, and
wherein the trigger signal indicates to the sensor to transition from a transmitting mode of operation to a receiving mode of operation to receive data encoded in the plurality of data bit groups.

2. The device of claim 1, wherein the trigger signal occurs for a length of time that indicates to the sensor to transition from the transmitting mode of operation to the receiving mode of operation, and
wherein the length of time of the trigger signal is from among a plurality of predetermined lengths of time, with other ones of the plurality of predetermined lengths of time representing respective encoded sensor addresses or respective sensor configuration data.

3. The device of claim 2, wherein the length of time of the trigger signal that indicates to the sensor to transition from the transmitting mode of operation to the receiving mode of operation is greater than the other ones of the plurality of predetermined lengths of time.

4. The device of claim 1, wherein at least a portion of the plurality of data bit groups comprise encoded data indicative of an address of the sensor.

5. The device of claim 1, wherein:
the processing circuitry is configured to generate a time base reference for the device that is based upon a device clock frequency,
the trigger signal comprises at least four edges including two edges having a first direction and two edges having a second direction that is different than the first direction,
the time base reference of the device is encoded in the trigger signal as a length of time between two of the at least four edges having the same direction, and
the time base reference enables the sensor to calibrate a sensor clock frequency to decode data encoded in the plurality of data bit groups.

6. The device of claim 1, wherein the trigger signal comprises two consecutive pulses.

7. The device of claim 6, wherein the trigger signal comprises a further pulse that precedes the two consecutive pulses, and
wherein the further pulse has a length of time that represents an encoded address of the sensor or sensor configuration data.

8. The device of claim 2, wherein the trigger signal comprises two consecutive pulses, and
wherein a length of time of each of the two consecutive pulses is less than a minimum length of time of a trigger pulse defined in accordance with the PWM code protocol and indicates to the sensor to transition from the transmitting mode of operation to the receiving mode of operation.

9. The device of claim 2, wherein the trigger signal comprises two consecutive pulses, and
wherein the length of time of each of the two consecutive pulses is less than other ones of the plurality of predetermined lengths of time and indicates to the sensor to transition from the transmitting mode of operation to the receiving mode of operation.

10. The device of claim 1, wherein the data frame does not include a synchronization pulse.

11. The device of claim 1, wherein the communication circuitry is configured to:
transmit the trigger signal;
receive, from the sensor, a sensor time base reference that is based upon a sensor clock frequency; and
transmit the plurality of data bit groups to the sensor that are encoded based upon the sensor time base reference.

12. The device of claim 1, wherein the sensor is from among a plurality of sensors configured to receive the trigger signal, and
wherein the trigger signal (i) indicates to each one of the plurality of sensors to transition from a transmitting mode of operation to a receiving mode of operation, or (ii) indicates to only the sensor to transition from the transmitting mode of operation to the receiving mode of operation.

13. A sensor configured to communicate with a device via a communication path, the sensor comprising:
communication circuitry configured to receive a trigger signal that is transmitted to the communication path; and
processing circuitry configured to, in response to a measured length of time of the trigger signal corresponding to an encoded receive mode command, transition the sensor to a receiving mode of operation,
wherein the communication circuitry is configured, upon the sensor transitioning to the receiving mode of operation, to receive data encoded in a plurality of data bit groups that are transmitted to the communication path in accordance with a pulse width modulation (PWM) code protocol.

14. The sensor of claim 13, wherein the measured length of time of the trigger signal corresponding to the encoded receive mode command is from among a plurality of predetermined lengths of time, with other ones of the plurality of predetermined lengths of time representing respective encoded sensor addresses or respective sensor configuration data.

15. The sensor of claim 14, wherein the measured length of time of the trigger signal corresponding to the encoded receive mode command is greater than the other ones of the plurality of predetermined lengths of time.

16. The sensor of claim 13, wherein at least a portion of the plurality of data bit groups comprise encoded data indicative of an address of the sensor.

17. The sensor of claim 13, wherein the trigger signal corresponding to the encoded receive mode command comprises at least four edges including two edges having a first direction and two edges having a second direction that is different than the first direction, and
wherein the measured length of time of the trigger signal corresponding to the encoded receive mode command comprises a time period between one of the four edges having the first direction and another one of the four edges having the second direction.

18. The sensor of claim 17, wherein a time base reference of the device that is based upon a device clock frequency is encoded in the encoded receive mode command as a length of time between two of the at least four edges having the same direction, and
wherein the processing circuitry is configured to use the time base reference of the device to calibrate a sensor clock frequency to decode the data encoded in the plurality of data bit groups.

19. The sensor of claim 13, wherein the trigger signal corresponding to the encoded receive mode command comprises two consecutive pulses.

20. The sensor of claim 19, wherein the trigger signal corresponding to the encoded receive mode command comprises a further pulse that precedes the two consecutive pulses, and
wherein the further pulse has a length of time that represents an encoded address of the sensor.

21. The sensor of claim 20, wherein the trigger signal corresponding to the encoded receive mode command comprises two consecutive pulses, and
wherein the measured length of time of the two consecutive pulses is less than a minimum length of time of a trigger pulse defined in accordance with the PWM code protocol and indicates to the sensor to transition to the receiving mode of operation.

22. The sensor of claim 14, wherein the trigger signal corresponding to the encoded receive mode command comprises two consecutive pulses, and
wherein the measured length of time of each of the two consecutive pulses is less than other ones of the plurality of predetermined lengths of time and indicates to the sensor to transition to the receiving mode of operation.

23. The sensor of claim 13, wherein the communication circuitry is configured to transmit, in accordance with the PWM code protocol, a sensor time base reference to the device that is based upon a sensor clock frequency, and
wherein the plurality of data bit groups are encoded based upon the sensor time base reference.
